(19) United States
(12) Patent Application Publication
(10) Pub. No.: US 2026/0271277 A1
(43) Pub. Date: Sep. 10, 2026

(54) DIGIT LINE FORMATION IN VERTICAL THREE-DIMENSIONAL (3D) MEMORY

(71) Applicant: Micron Technology, Inc., Boise, ID (US)

(72) Inventors: Benben Li, Boise, ID (US); Cheng Li, Boise, ID (US)

(21) Appl. No.: 19/556,609

(22) Filed: Mar. 4, 2026

Related U.S. Application Data
(60) Provisional application No. 63/767,979, filed on Mar. 6, 2025.

(51) Int. Cl. H10B 12/00; H10D 30/67; H10D 62/83; H10W 20/00; H10W 20/46

(52) U.S. Cl. CPC H10B 12/482; H10B 12/05; H10D 30/6735; H10D 30/6744; H10D 62/83; H10W 20/056; H10W 20/072; H10W 20/46

(57) ABSTRACT

Systems, methods and apparatus are provided for an array of vertically stacked memory cells having horizontally oriented access devices and storage nodes. The horizontally oriented access devices include first source/drain regions and a second source/drain regions separated by channel regions. Gates at the channel regions formed fully around every surface of the channel region as gate-all-around (GAA) structures separated from channel regions by gate dielectrics. The memory cells have horizontally oriented storage nodes connected to the second source/drain regions and digit lines connected to the first source/drain regions.

### PRIORITY INFORMATION

This application claims the benefit of U.S. Provisional Application Number 63/767,979, filed on March 6, 2025, the contents of which are incorporated herein by reference.

### TECHNICAL FIELD

The present disclosure relates generally to memory devices, and more particularly, to digit line formation in vertical three-dimensional (3D) memory

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain regions separated by epitaxially grown channel regions. A gate may oppose the channel region and be separated therefrom by a gate dielectric. An access line, such as a word line, is electrically connected to the gate of the DRAM cell. A DRAM cell can include a storage node, such as a capacitor cell, connected by the access device to a digit line. The access device can be activated (e.g., to select the cell) by an access line connected to the access transistor. The capacitor can store a charge corresponding to a data value of a respective cell (e.g., a logic “1” or “0”).

### BRIEF DESCRIPTION OF THE DRAWINGS

FIG. 1A is a schematic illustration of a horizontal access device in a vertical three-dimensional (3D) memory in accordance a number of embodiments of the present disclosure.

FIG. 1B is a perspective view illustrating a portion of a horizontal access device in vertical three-dimensional (3D) memory in accordance with a number of embodiments of the present disclosure.

FIG. 2 illustrates a portion of a horizontal access device in vertical three-dimensional (3D) memory in accordance with a number of embodiments of the present disclosure.

FIG. 3 illustrates a portion of a vertical 3D memory array in accordance with a number of embodiments of the present disclosure.

FIG. 4 is a cross-sectional view, at one stage of a semiconductor fabrication process, for digit line formation in vertical three-dimensional (3D) memory, in accordance with a number of embodiments of the present disclosure.

FIGS. 5A to 5B illustrate an example method, at one stage of a semiconductor fabrication process, for epitaxial digit line growth in vertical three-dimensional (3D) memory, in accordance with a number of embodiments of the present disclosure.

FIGS. 6A to 5B illustrate an example method, at one stage of a semiconductor fabrication process, for digit line formation in vertical three-dimensional (3D) memory, in accordance with a number of embodiments of the present disclosure.

FIGS. 7A to 7C illustrate an example method, at one stage of a semiconductor fabrication process, for digit line formation in vertical three-dimensional (3D) memory, in accordance with a number of embodiments of the present disclosure.

FIG. 8 illustrates an example method, at one stage of a semiconductor fabrication process, for digit line formation in vertical three-dimensional (3D) memory, in accordance with a number of embodiments of the present disclosure.

FIGS. 9A to 9C illustrate an example method, at one stage of a semiconductor fabrication process, for digit line formation in vertical three-dimensional (3D) memory, in accordance with a number of embodiments of the present disclosure.

FIGS. 10A to 10B illustrate an example method, at one stage of a semiconductor fabrication process, for digit line formation in vertical three-dimensional (3D) memory, in accordance with a number of embodiments of the present disclosure.

FIGS. 11A to 11C illustrate an example method, at one stage of a semiconductor fabrication process, for digit line formation in vertical three-dimensional (3D) memory, in accordance with a number of embodiments of the present disclosure.

FIGS. 12A to 12B illustrate an example method, at one stage of a semiconductor fabrication process, for digit line formation in vertical three-dimensional (3D) memory, in accordance with a number of embodiments of the present disclosure.

FIGS. 13A to 13B illustrate an example method, at one stage of a semiconductor fabrication process, for digit line formation in vertical three-dimensional (3D) memory, in accordance with a number of embodiments of the present disclosure.

FIGS. 14A to 14B illustrate an example method, at one stage of a semiconductor fabrication process, for digit line formation in vertical three-dimensional (3D) memory, in accordance with a number of embodiments of the present disclosure.

FIGS. 15A to 15B illustrate an example method, at one stage of a semiconductor fabrication process, for digit line formation in vertical three-dimensional (3D) memory, in accordance with a number of embodiments of the present disclosure.

FIGS. 16A to 16B illustrate an example method, at one stage of a semiconductor fabrication process, for digit line formation in vertical three-dimensional (3D) memory, in accordance with a number of embodiments of the present disclosure.

FIG. 17 is a block diagram of an apparatus in the form of a computing system including a memory device in accordance with a number of embodiments of the present disclosure.

### DETAILED DESCRIPTION

Embodiments of the present disclosure describe epitaxial digit line growth in vertical three-dimensional (3D) memory. A vertically oriented digit line is formed with horizontally oriented access devices and access lines in an array of vertically stacked memory cells. The horizontal access devices are integrated with horizontally oriented access lines having a first source/drain regions and a second source/drain regions separated by channel regions and integrated with vertically oriented digit lines. In vertically stacked memory array structures, such as transistor structures, polycrystalline silicon (also referred to as polysilicon) can be leaky, allowing current to leak through the polycrystalline structure, making the transistor less effective. Single crystal silicon is not very leaky. However, single crystal silicon cannot grow on amorphous dielectric materials, such as oxides or nitrides, which are the common materials upon which transistors are formed.

However, as disclosed in the embodiments of the present disclosure, it is possible to use a silicon wafer for a transistor that can be utilized as a substrate during the high temperature processes required for single crystal silicon formation. In such embodiments, a layer of silicon germanium can be grown on the silicon substrate. Single crystal silicon can, then, be grown on the silicon germanium.

This may be accomplished, for example, by providing a thin single crystal silicon germanium layer, as a seed layer, and then forming the single crystal silicon germanium layer thickness. Once the desired layer thickness is formed, a silicon layer can be formed into the surface of the silicon germanium layer. As with the silicon germanium layer, this may be accomplished, for example, by providing a thin single crystal silicon layer, as a seed layer, and then forming the thin single crystal silicon layer thickness into a thicker single crystal silicon layer.

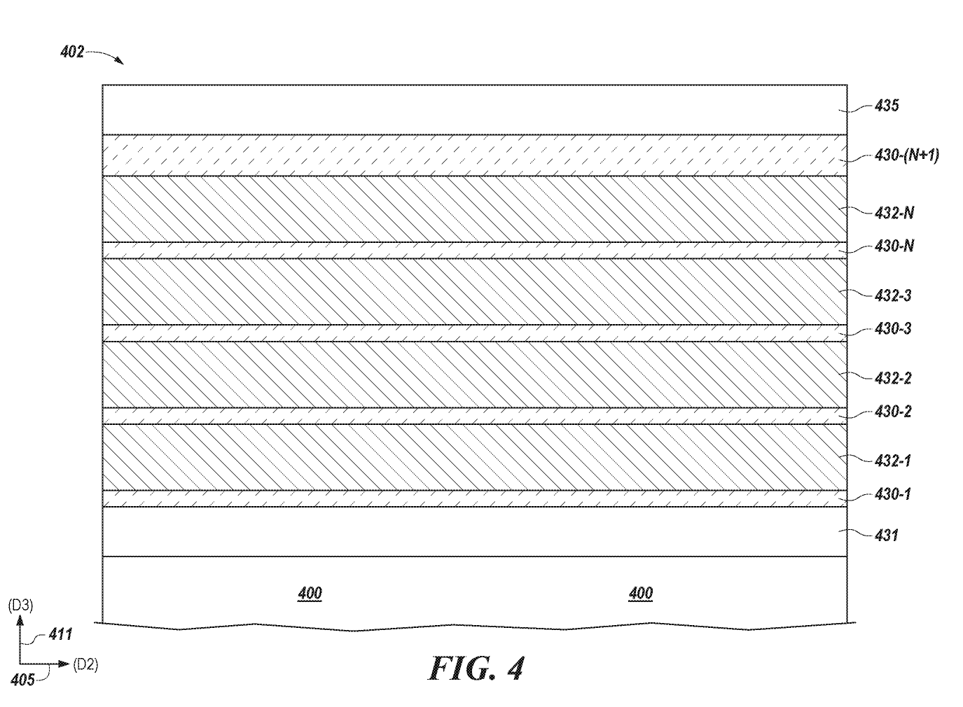

Depending on the silicon germanium concentration, if silicon is x quantity and germanium is y quantity and, if y is smaller than x, then silicon/silicon germanium has a small lattice mismatch with respect to the lattice of single crystal silicon. This allows silicon to be formed on top of silicon germanium with a single crystal structure. If a thin layer of single crystal silicon is applied to the surface of the silicon germanium, then the whole silicon layer acts as a seed for the growth of the single crystal silicon layer. Such layering can be done in alternating iterations (e.g., SiGe/Si/SiGe/Si, etc.) to create a superlattice structure in the form of a vertical stack such as shown in FIG. 4.

For example, a seed layer of silicon germanium can be formed that is 100 Angstroms in thickness (height) and can be grown to, for example 1000 Angstroms. A thin silicon seed layer can be formed on the surface of the silicon germanium layer that is, for example, 50 Angstroms and can be grown to a thickness of, for example, 300 Angstroms. These thicknesses are merely provided as examples and should not be regarded as limiting unless recited explicitly in a particular claim.

The transistor devices of the present disclosure will have better performance with regard to I-on, better I-off, drivability, and/or leakage current because there is no grain boundary and therefore current cannot leak through the grain boundary which is where leakage often occurs in polysilicon. In some embodiments, devices can have, for example, three orders of magnitude lower I-off (leakage).

Advantages to the structure and process described herein can include a lower off-current (Ioff) for the access devices, as compared to silicon based (Si-based) access devices (e.g., transistors), better DRAM refresh requirement, and/or reduced gate/drain induced leakage (GIDL) for the access devices. Combined with a gate all around (GAA) structure at the channel region of the semiconductor material, provides better electrostatic control on the channel, better subthreshold slope and a more cost-effective process.

During formation of the 3D memory array, one step in the semiconductor fabrication process can include forming digit lines. In the process described herein, the digit lines can be vertically oriented in the 3D memory array. The digit lines can be formed in a vertical opening in the 3D memory array to conductively interconnect memory cells along vertical columns.

In some examples, the vertical columns are high aspect ratio spaces. Therefore, forming vertically oriented digit lines within the vertical column can ensure that the digit lines extend the full depth of the vertical columns and continuously touch every Si channel in the vertical columns.

However, using Si material when forming vertical digit lines can include risks of horizontal shorting. For example, epitaxial growth of Si material can occur both vertically as well as horizontally. Additionally, deposition of Si material can occur both vertically as well as horizontally. Accordingly, a risk of horizontal merging of Si material comprising the vertical digit line is present. If such horizontal merging occurs, laterally adjacent vertically oriented digit lines may be electrically shorted together.

Digit line formation in vertical 3D memory according to the disclosure can allow for formation of vertical digit lines without horizontal merging occurring. For example, spaced vertical columns can be utilized to prevent horizontal merging of adjacent vertical digit lines. The spaced vertical columns can be utilized in order to prevent laterally adjacent vertically oriented digit lines from being electrically shorted together, as is described herein.

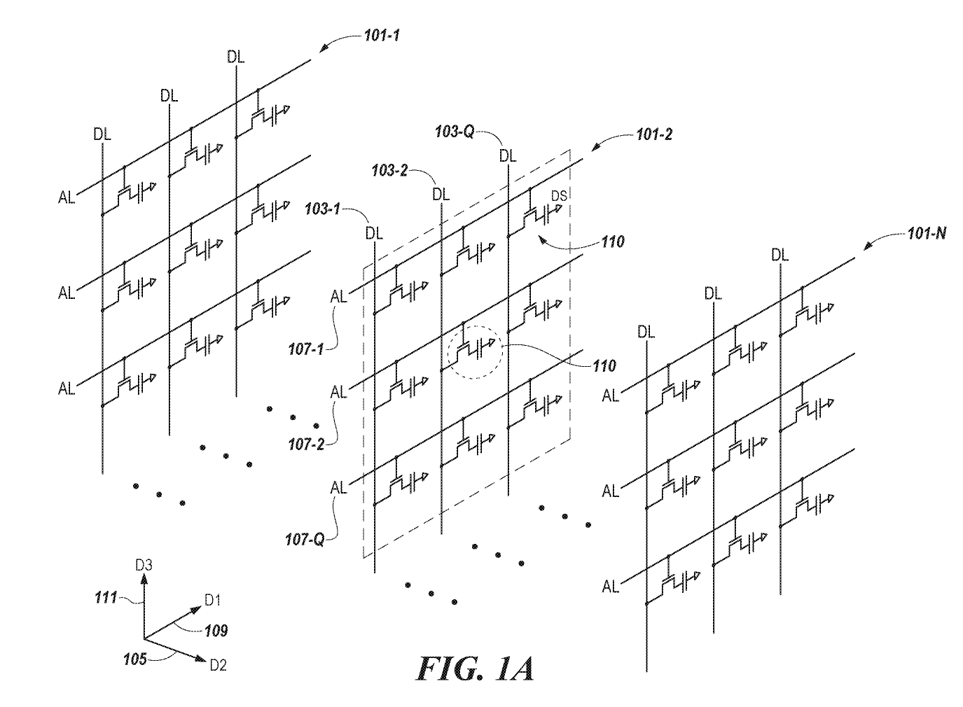

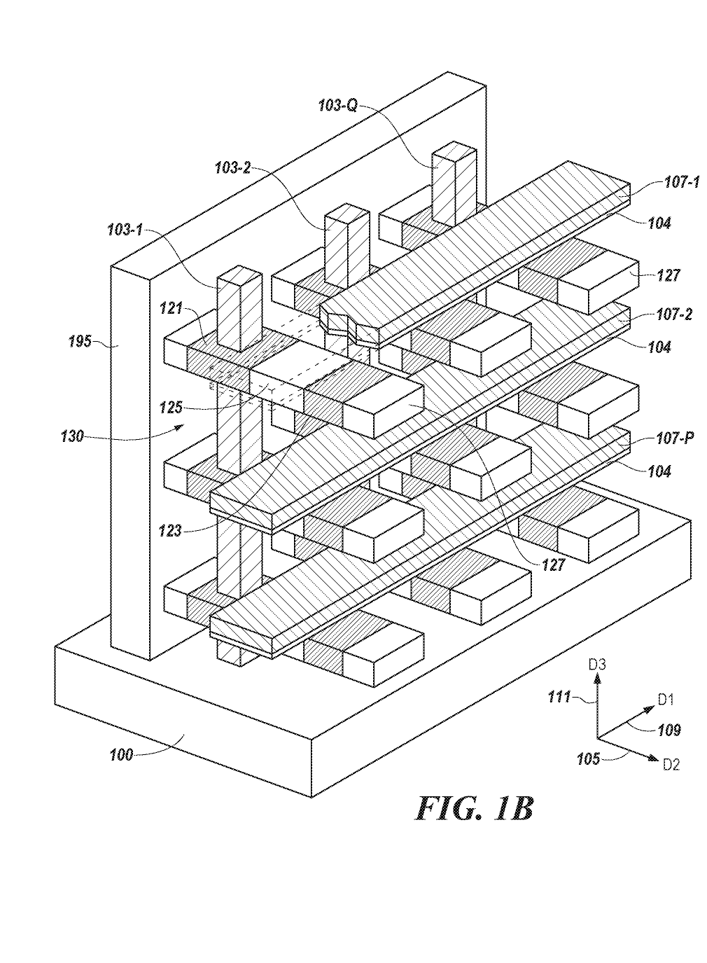

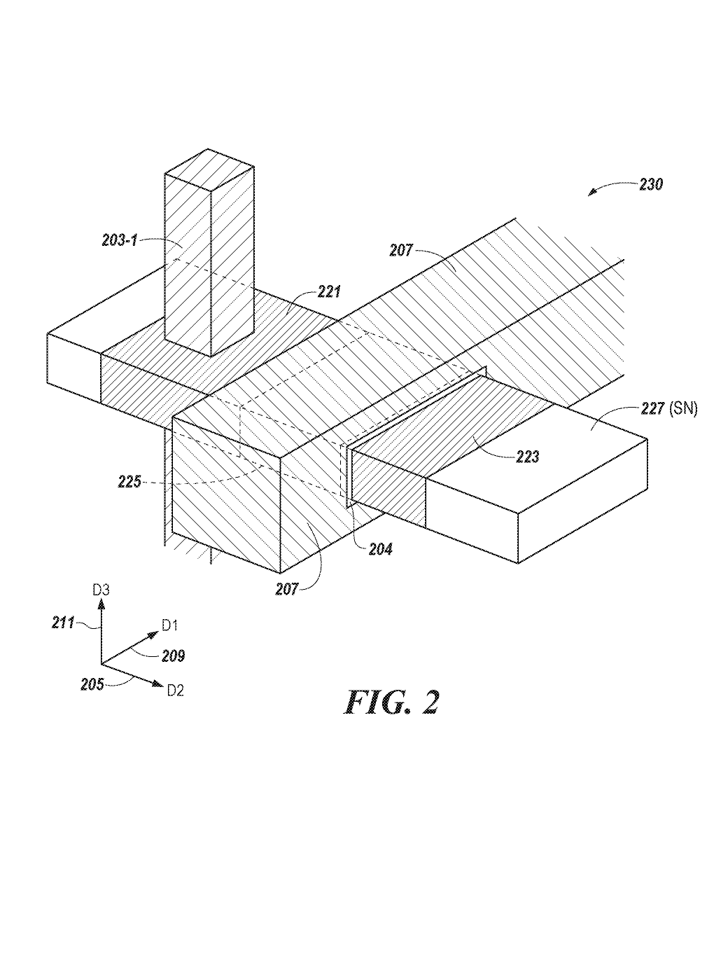

The figures herein follow a numbering convention in which the first digit or digits correspond to the figure number of the drawing and the remaining digits identify an element or component in the drawing. Similar elements or components between different figures may be identified by the use of similar digits. For example, reference numeral 103 may reference element “03” in FIG. 1, and a similar element may be referenced as 203 in FIG. 2. Multiple analogous elements within one figure may be referenced with a reference numeral followed by a hyphen and another numeral or a letter. For example, 302-1 may reference element 302-1 in FIG. 3 and 302-2 may reference element 302-2, which may be analogous to element 302-1. Such analogous elements may be generally referenced without the hyphen and extra numeral or letter. For example, elements 302-1 and 302-2 or other analogous elements may be generally referenced as 302.

FIG. 1A is a schematic illustration of a horizontal access device in a vertical three-dimensional (3D) memory in accordance with a number of embodiments of the present disclosure. FIG. 1A illustrates a circuit diagram showing a cell array of a 3D semiconductor memory device according to embodiments of the present disclosure. FIG. 1A illustrates that a cell array may have a plurality of sub cell arrays 101-1, 101-2, . . ., 101-N. The sub cell arrays 101-1, 101-2, . . ., 101-N may be arranged along a second direction (D2) 105. Each of the sub cell arrays, e.g., sub cell array 101-2, may include a plurality of access lines 107-1, 107-2, . . ., 107-Q (which also may be referred to as word lines). Also, each of the sub cell arrays, e.g., sub cell array 101-2, may include a plurality of digit lines 103-1, 103-2, . . ., 103-Q (which also may be referred to as bit lines, data lines, or sense lines). In FIG. 1A, the access lines 107-1, 107-2, . . ., 107-Q are illustrated extending in a first direction (D1) 109 and the digit lines 103-1, 103-2, . . ., 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . ., 103-Q are extending in a vertical direction, e.g., third direction (D3) 111.

A memory cell, e.g., memory cell 110, may include an access device, e.g., access transistor, and a storage node located at an intersection of each access line 107-1, 107-2, . . ., 107-Q and each digit line 103-1, 103-2, . . ., 103-Q. Memory cells may be written to, or read from, using the access lines 107-1, 107-2, . . ., 107-Q and digit lines 103-1, 103-2, . . ., 103-Q. The access lines 107-1, 107-2, . . ., 107-Q may conductively interconnect memory cells along horizontal rows of each sub cell array 101-, 101-2, . . ., 101-N, and the digit lines 103-1, 103-2, . . ., 103-Q may conductively interconnect memory cells along vertical columns of each sub cell array 101-, 101-2, . . ., 101-N. One memory cell, e.g. 110, may be located between one access line, e.g., 107-2, and one digit line, e.g., 103-2. Each memory cell may be uniquely addressed through a combination of an access line 107-1, 107-2, . . ., 107-Q and a digit line 103-1, 103-2, . . ., 103-Q.

The access lines 107-1, 107-2, . . ., 107-Q may be or include conducting patterns (e.g., metal lines) disposed on and spaced apart from a substrate. The access lines 107-1, 107-2, . . ., 107-Q may extend in a first direction (D1) 109. The access lines 107-1, 107-2, . . ., 107-Q in one sub cell array, e.g., 101-2, may be spaced apart from each other in a vertical direction, e.g., in a third direction (D3) 111.

The digit lines 103-1, 103-2, . . ., 103-Q may be or include conductive patterns (e.g., metal lines) extending in a vertical direction with respect to the substrate, e.g., in a third direction (D3) 111. The digit lines in one sub cell array, e.g., 101-2, may be spaced apart from each other in the first direction (D1) 109.

A gate of a memory cell, e.g., memory cell 110, may be connected to an access line, e.g., 107-2, and a first conductive node, e.g., first source/drain region, of an access device, e.g., transistor, of the memory cell 110 may be connected to a digit line, e.g., 103-2. Each of the memory cells, e.g., memory cell 110, may be connected to a storage node, e.g., capacitor. A second conductive node, e.g., second source/drain region, of the access device, e.g., transistor, of the memory cell 110 may be connected to the storage node, e.g., capacitor. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line, e.g., 103-2, and the other may be connected to a storage node.

FIG. 1B is a perspective view illustrating a portion of a horizontal access device in vertical three-dimensional (3D) memory, e.g., a portion of a sub cell array 101-2 shown in FIG. 1A as a vertically oriented stack of memory cells in an array, in accordance with a number of embodiments of the present disclosure.

As shown in FIG. 1B, a substrate 100 may have formed thereon one of the plurality of sub-cell arrays, e.g., 101-2, described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells, e.g., memory cell 110 in FIG. 1A, extending in a vertical direction, e.g., third direction (D3) 111. According to some embodiments the vertically oriented stack of memory cells may be fabricated such that each memory cell, e.g., memory cell 110 in FIG. 1A, is formed on plurality of vertical levels, e.g., a first level (L1), a second level (L2), and a third level (L3). The repeating, vertical levels, L1, L2, and L3, may be arranged, e.g., “stacked”, a vertical direction, e.g., third direction (D3) 111 shown in FIG. 1A, and may be separated from the substrate 100 by an insulator material. Each of the repeating, vertical levels, L1, L2, and L3 may include a plurality of discrete components, e.g., regions, to the horizontally oriented access devices 130, e.g., transistors, and storage nodes, e.g., capacitors, including access line 107-1, 107-2, . . ., 107-Q connections and digit line 103-1, 103-2, . . ., 103-Q connections. The plurality of discrete components to the horizontally oriented access devices 130, e.g., transistors, may be formed in a plurality of iterations of vertically, repeating layers within each level, as described in more detail below, and may extend horizontally in the second direction (D2) 105, analogous to second direction (D2) 105 shown in FIG. 1A.

The plurality of discrete components to the laterally oriented access devices 130, e.g., transistors, may include a first source/drain region 121 and a second source/drain region 123 separated by a channel region 125, extending laterally in the second direction (D2) 105, and formed in a body of the access devices. In some embodiments, the channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127, e.g., capacitor, may be connected to one respective end of the access device. As shown in FIG. 1B, the storage node 127, e.g., capacitor, may be connected to the second source/drain region 123 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1A, may similarly extend in the second direction (D2) 105, analogous to second direction (D2) 105 shown in FIG. 1A.

As shown in FIG. 1B a plurality of horizontally oriented access lines 107-1, 107-2, . . ., 107-Q extend in the first direction (D1) 109, analogous to the first direction (D1) 109 in FIG. 1A. The plurality of horizontally oriented access lines 107-1, 107-2, . . ., 107-Q may be analogous to the access lines 107-1, 107-2, . . ., 107-Q shown in FIG. 1A. The plurality of horizontally oriented access lines 107-1, 107-2, . . ., 107-Q may be arranged, e.g., “stacked”, along the third direction (D3) 111. The plurality of horizontally oriented access lines 107-1, 107-2, . . ., 107-Q may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, (L1), (L2), and (L3), the horizontally oriented memory cells, e.g., memory cell 110 in FIG. 1A, may be spaced apart from one another horizontally in the first direction (D1) 109. However, the plurality of discrete components to the horizontally oriented access devices 130, e.g., first source/drain region 121 and second source/drain region 123 separated by a channel region 125, extending laterally in the second direction (D2) 105, and the plurality of horizontally oriented access lines 107-1, 107-2, . . ., 107-Q extending laterally in the first direction (D1) 109, may be formed within different vertical layers within each level. For example, the plurality of horizontally oriented access lines 107-1, 107-2, . . ., 107-Q, extending in the first direction (D1) 109, may be formed on a top surface opposing and electrically connected to the channel regions 125, separated therefrom by a gate dielectric, and orthogonal to horizontally oriented access devices 130, e.g., transistors, extending in laterally in the second direction (D2) 105. In some embodiments, the plurality of horizontally oriented access lines 107-1, 107-2, . . ., 107-Q, extending in the first direction (D1) 109 are formed in a higher vertical layer, farther from the substrate 100, within a level, e.g., within level (L1), than a layer in which the discrete components, e.g., first source/drain region 121 and second source/drain region 123 separated by a channel region 125, of the horizontally oriented access device are formed.

As shown in the example embodiment of FIG. 1B, the digit lines, 103-1, 103-2, . . ., 103-Q, extend in a vertical direction with respect to the substrate 100, e.g., in a third direction (D3) 111. Further, as shown in FIG. 1B, the digit lines, 103-1, 103-2, . . ., 103-Q, in one sub cell array, e.g., sub cell array 101-2 in FIG. 1A, may be spaced apart from each other in the first direction (D1) 109. The digit lines, 103-1, 103-2, . . ., 103-Q, may be provided, extending vertically relative to the substrate 100 in the third direction (D3) 111 in vertical alignment with source/drain regions to serve as first source/drain regions 121 or, as shown, be vertically adjacent first source/drain regions 121 for each of the horizontally oriented access devices 130, e.g., transistors, extending laterally in the second direction (D2) 105, but adjacent to each other on a level, e.g., first level (L1), in the first direction (D1) 109. Each of the digit lines, 103-1, 103-2, . . ., 103-Q, may vertically extend, in the third direction (D3), on sidewalls, adjacent first source/drain regions 121, of respective ones of the plurality of horizontally oriented access devices 130, e.g., transistors, that are vertically stacked. In some embodiments, the plurality of vertically oriented digit lines 103-1, 103-2, . . ., 103-Q, extending in the third direction (D3) 111, may be connected to side surfaces of the first source/drain regions 121 directly and/or through additional contacts including metal silicides.

For example, a first one of the vertically extending digit lines, e.g., 103-1, may be adjacent a sidewall of a first source/drain region 121 to a first one of the horizontally oriented access devices 130, e.g., transistors, in the first level (L1), a sidewall of a first source/drain region 121 of a first one of the horizontally oriented access devices 130, e.g., transistors, in the second level (L2), and a sidewall of a first source/drain region 121 a first one of the horizontally oriented access devices 130, e.g., transistors, in the third level (L3), etc. Similarly, a second one of the vertically extending digit lines, e.g., 103-2, may be adjacent a sidewall to a first source/drain region 121 of a second one of the horizontally oriented access devices 130, e.g., transistors, in the first level (L1), spaced apart from the first one of horizontally oriented access devices 130, e.g., transistors, in the first level (L1) in the first direction (D1) 109. And the second one of the vertically extending digit lines, e.g., 103-2, may be adjacent a sidewall of a first source/drain region 121 of a second one of the laterally oriented access devices 130, e.g., transistors, in the second level (L2), and a sidewall of a first source/drain region 121 of a second one of the horizontally oriented access devices 130, e.g., transistors, in the third level (L3), etc. Embodiments are not limited to a particular number of levels.

The vertically extending digit lines, 103-1, 103-2, . . ., 103-Q, may include a conductive material, such as, for example, one of a doped semiconductor material, a conductive metal nitride, metal, and/or a metal-semiconductor compound. The digit lines, 103-1, 103-2, . . ., 103-Q, may correspond to digit lines (DL) described in connection with FIG. 1A.

As shown in the example embodiment of FIG. 1B, a conductive body contact may be formed extending in the first direction (D1) 109 along an end surface of the horizontally oriented access devices, e.g., transistors, in each level (L1), (L2), and (L3) above the substrate 100. The body contact may be connected to a body e.g., body region, of the horizontally oriented access devices, e.g., transistors, in each memory cell, e.g., memory cell 110 in FIG. 1A. The body contact may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates a portion of a horizontal access device in vertical three-dimensional (3D) memory in accordance with a number of embodiments of the present disclosure. FIG. 2 illustrates in more detail a unit cell, e.g., memory cell 110 in FIG. 1, of the vertically stacked array of memory cells, e.g., within a sub cell array 101-2 in FIG. 1, according to some embodiments of the present disclosure. As shown in FIG. 2, the first and the second source/drain regions, 221 and 223, may be impurity doped regions to the laterally oriented access devices 230, e.g., transistors. The first and the second source/drain regions may be separated by a channel region 225 formed in a body of semiconductor material, e.g., body region of the horizontally oriented access devices 230, e.g., transistors. The first and the second source/drain regions, 221 and 223, may be formed from an n-type or p-type dopant doped in the body region. However, embodiments are not so limited.

For example, for an n-type conductivity transistor construction the body region of the laterally oriented access devices 230, e.g., transistors, may be formed of a low doped p-type (p-) semiconductor material. In one embodiment, the body region and the channel region 225 separating the first and the second source/drain regions, 221 and 223, may include a low doped, p-type (e.g., low dopant concentration (p-)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In2O3), or indium tin oxide (In2-xSnxO3), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 230, e.g., transistors, may be of a p-type conductivity construction in which case the impurity, e.g., dopant, conductivity types would be reversed.

As shown in FIG. 2, the first and the second source/drain regions, 221 and 223, may be impurity doped regions to the laterally oriented access devices 230, e.g., transistors. The first and the second source/drain regions may be separated by a channel region 225 formed in a body of semiconductor material, e.g., body region, of the horizontally oriented access devices 230, e.g., transistors. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 221 and is in electrical contact with the body contact. Further, as shown in the example embodiment of FIG. 2, an access line, e.g., 207, analogous to the access lines 107-1, 107-2, . . ., 107-Q shown in FIG. 1, may disposed on a top surface opposing and connected to a channel region 225, separated therefrom by a gate dielectric 204. The gate dielectric 204 may be, for example, a high-k dielectric material, a silicon oxide material, a silicon nitride material, a silicon oxynitride material, etc., or a combination thereof. Embodiments are not so limited. For example, in high-k dielectric material examples the gate dielectric material 304 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digit line, e.g., 203-1, analogous to the digit lines 103-1, 103-2, . . ., 103-Q in FIG. 1, may be vertically extending in the third direction (D3) 211 adjacent a sidewall of the first source/drain region 221 in the body to the horizontally oriented access devices 230, e.g., transistors horizontally conducting between the first and the second source/drain regions 221 and 223 along the second direction (D2) 205. In this embodiment, the vertically oriented digit line 203-1 is formed symmetrically, in vertical alignment, in electrical contact with the first source/drain region 221. The digit line 203-1 may be formed in contact with an insulator material such that there is no body contact within channel region 225.

As shown in the example embodiment of FIG. 2, the digit line 203-1 may be formed symmetrically within the first source/drain region 221 such that the first source/drain region 221 surrounds the digit line 203-1 all around. The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 321 and is in contact with the body contact. An insulator material may fill the body contact such that the first source/drain region 221 may not be in electrical contact with channel region 225. Further, as shown in the example embodiment of FIG. 2, an access line, e.g., 207, analogous to the access lines 107-1, 107-2, . . ., 107-Q shown in FIG. 1, may disposed all around and connected to a channel region 225, separated therefrom by a gate dielectric 204.

Although the digit line 203-1 is described above as being formed symmetrically within the first source/drain region 221 such that the first source/drain region 221 surrounds the digit line 203-1 all around, embodiments are not so limited. For instance, in some examples, the digit line 203-1 can be formed asymmetrically. In this embodiment, the vertically oriented digit line is formed asymmetrically adjacent in electrical contact with the first source/drain regions 221. The digit line may be formed asymmetrically to reserve room for a body contact in the channel region 225.

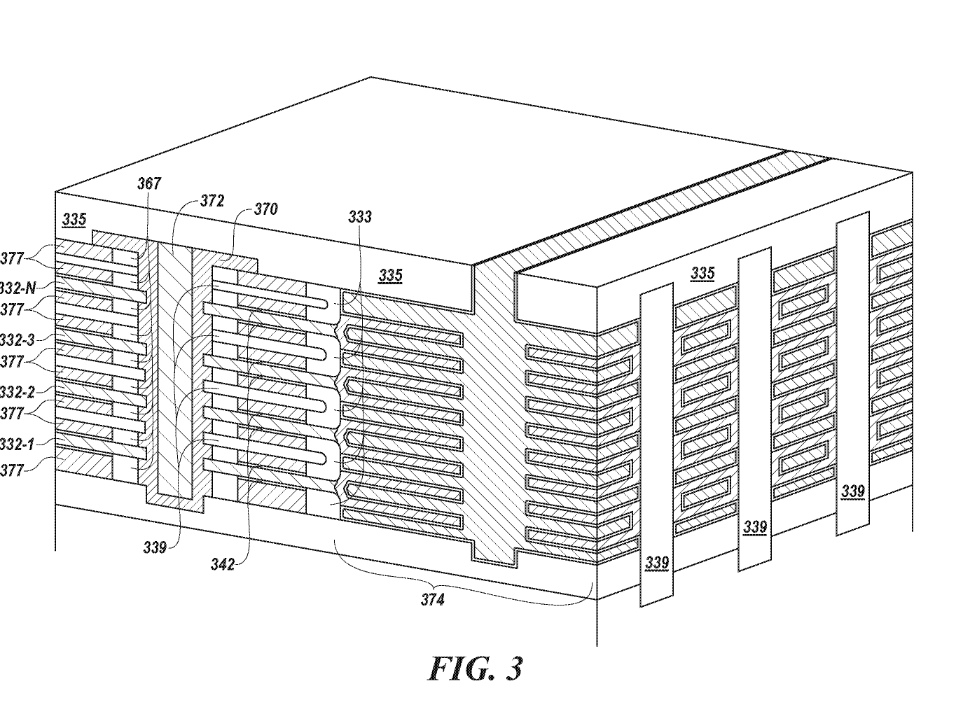

FIG. 3 illustrates a portion of a vertical 3D memory array that is formed in accordance with the process described in FIGS. 4-16, as is further described herein. The 3D memory array can include an array of vertically stacked memory cells having a plurality of levels. Each level of the plurality of levels can include horizontally oriented access devices and storage nodes. FIG. 3 includes first conductive material 377, an Si material 332, a photolithographic mask material (e.g., mask material) 335, an interlayer dielectric (ILD) fill material 367, a second conductive material 370, a metal material 372, a first dielectric material 339, a second dielectric material 333, a second interlayer dielectric material 342, and a plurality of storage nodes (e.g., capacitors) 374.

Each storage node can include horizontally oriented access devices having first source/drain regions and second source/drain regions separated by channel regions, and gates on a gate dielectric material. The array can further comprise horizontally oriented access lines forming the gates to the horizontally oriented access devices. The horizontally oriented access lines can be gate all around (GAA) structures. The storage nodes can further include horizontally oriented storage nodes electrically connected to the second source/drain regions of the horizontally oriented access devices.

The horizontal access devices of the vertical 3D memory array can include the second dielectric material 333, the first dielectric material 377, a first dielectric material 339, and ILD fill material 367. The access devices can be connected to the plurality of storage nodes 374. In some embodiments, the plurality of storage nodes 374 can be double-sided capacitors. The access devices can be used to transfer current between the metal material 372 and the plurality of storage nodes 374.

Further included in the vertical 3D memory array are vertical digit lines 392 connected to the first source/drain regions of the horizontally oriented access devices. Devices and methods of forming the vertical digit lines are further described herein.

FIG. 4 is a cross-sectional view, at one stage of a semiconductor fabrication process, for digit line formation in vertical three-dimensional (3D) memory, such as illustrated in FIGS. 1-3, and in accordance with a number of embodiments of the present disclosure.

In the example embodiment shown in the example of FIG. 4, the method comprises forming alternating layers of a silicon germanium (SiGe) material , 430-1, 430-2, . . ., 430-N (collectively referred to as silicon germanium (SiGe) 430), and a silicon (Si) material, 432-1, 432-2, . . ., 432-N (collectively referred to as epitaxially grown, single crystalline silicon (Si) material 432), in repeating iterations to form a vertical stack 402 on a working surface of a semiconductor substrate 400. In one embodiment, the silicon germanium (SiGe) 430 can be deposited on a dielectric 431 to have a thickness, e.g., vertical height in the third direction (D3), in a range of five (5) nm to thirty (30) nm. In one embodiment, the silicon 432 can be deposited to have a thickness (t2), e.g., vertical height, in a range of thirty (30) nanometers (nm) to sixty (60) nm. Embodiments, however, are not limited to these examples. As shown in FIG. 4, a vertical direction 411 is illustrated as a third direction (D3), e.g., z-direction in an x-y-z coordinate system, analogous to the third direction (D3), among first, second, and third directions, shown in FIGS. 1-2.

In some embodiments, the silicon germanium (SiGe), 430-1, 430-2, . . ., 430-N, may be a mix of silicon and germanium. By way of example, and not by way of limitation, the silicon germanium (SiGe) 430 may be grown on a dielectric 431 by way of epitaxial growth. Embodiments are not limited to these examples. In some embodiments, the single crystalline silicon (Si) material, 432-1, 432-2, . . ., 432-N, may comprise a silicon (Si) material in a polycrystalline and/or amorphous state. The single crystalline silicon (Si) material, 432-1, 432-2, . . ., 432-N, may be a low doped, p-type (p-) epitaxially grown, single crystalline silicon (Si) material. The silicon material, 432-1, 432-2, . . ., 432-N, may also be formed by epitaxially growth on the silicon germanium (SiGe) 430. After the epitaxially grown silicon germanium (SiGe) 430 has been formed, the seed is turned to pure silicon. Embodiments, however, are not limited to these examples.

The repeating iterations of alternating silicon germanium (SiGe), 430-1, 430-2, . . ., 430-N layers and epitaxially grown, single crystalline silicon (Si) material, 432-1, 432-2, . . ., 432-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of epitaxially grown silicon germanium (SiGe) and epitaxially grown, single crystalline silicon (Si) material, in repeating iterations to form the vertical stack 402.

The layers may occur in repeating iterations vertically. In the example of FIG. 4, N+1 tiers, numbered 1, 2, 3, N, and N+1 of the repeating iterations are shown. For example, the stack may include: a first silicon germanium (SiGe) 430-1, a first Si material 432-1, a second SiGe material 430-2, a second Si material 432-2, a third SiGe material 430-3, and a Si material 432-3, in further repeating iterations. Embodiments, however, are not limited to this example and more or fewer repeating iterations may be included.

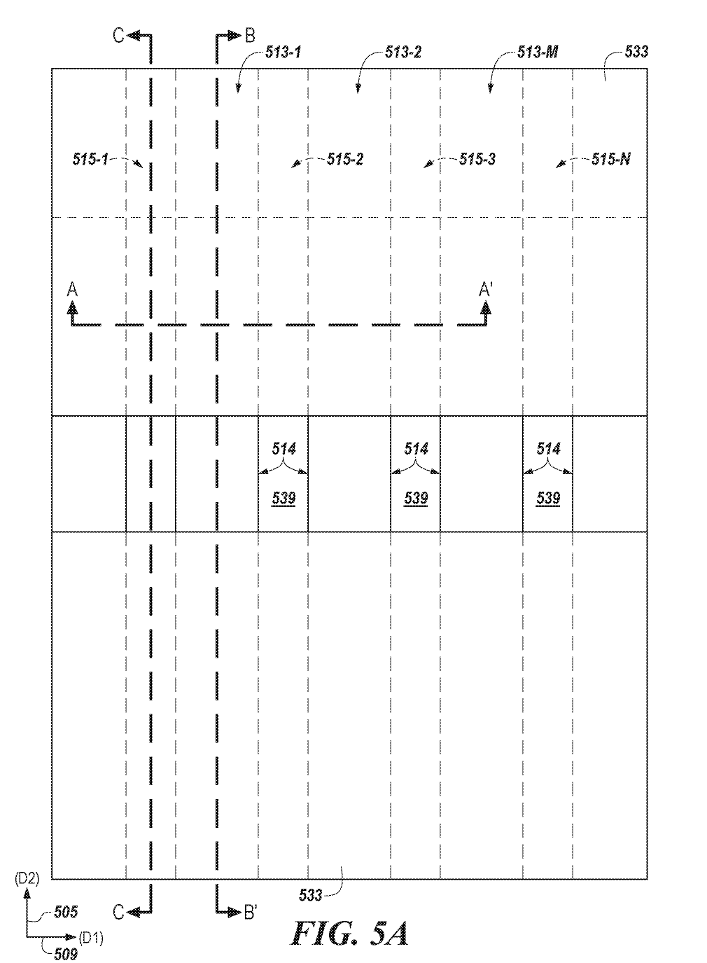

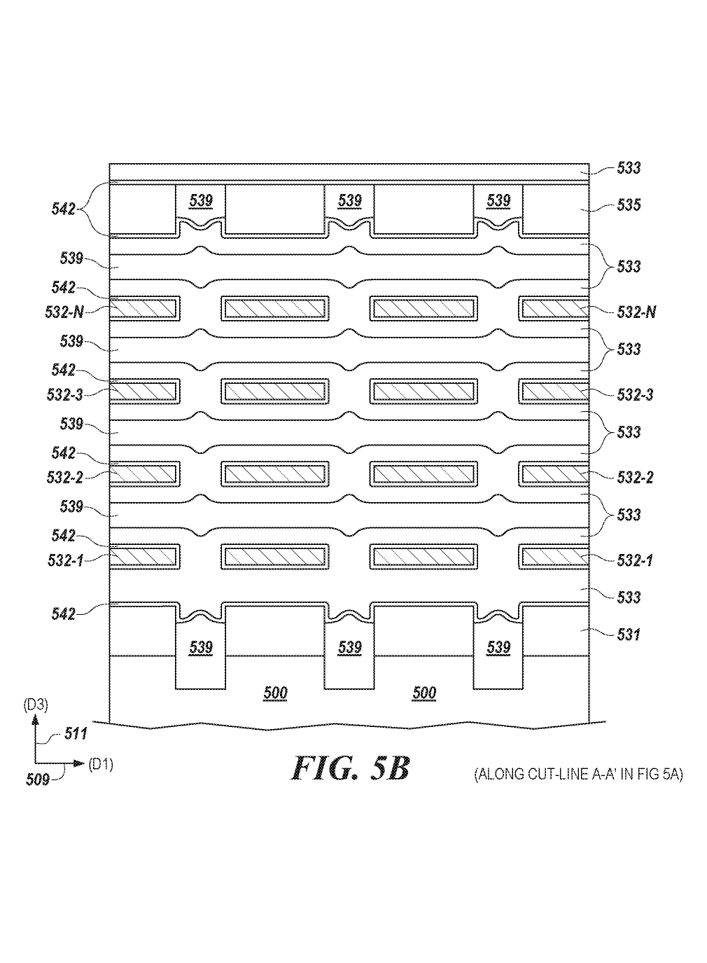

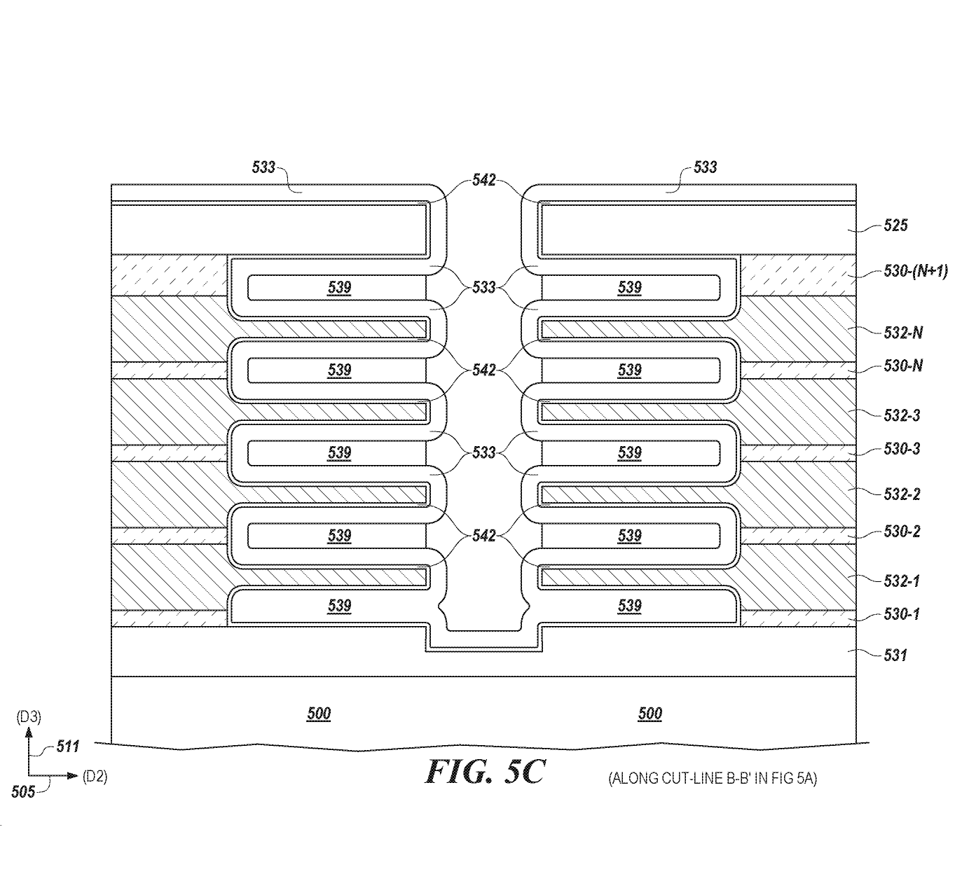

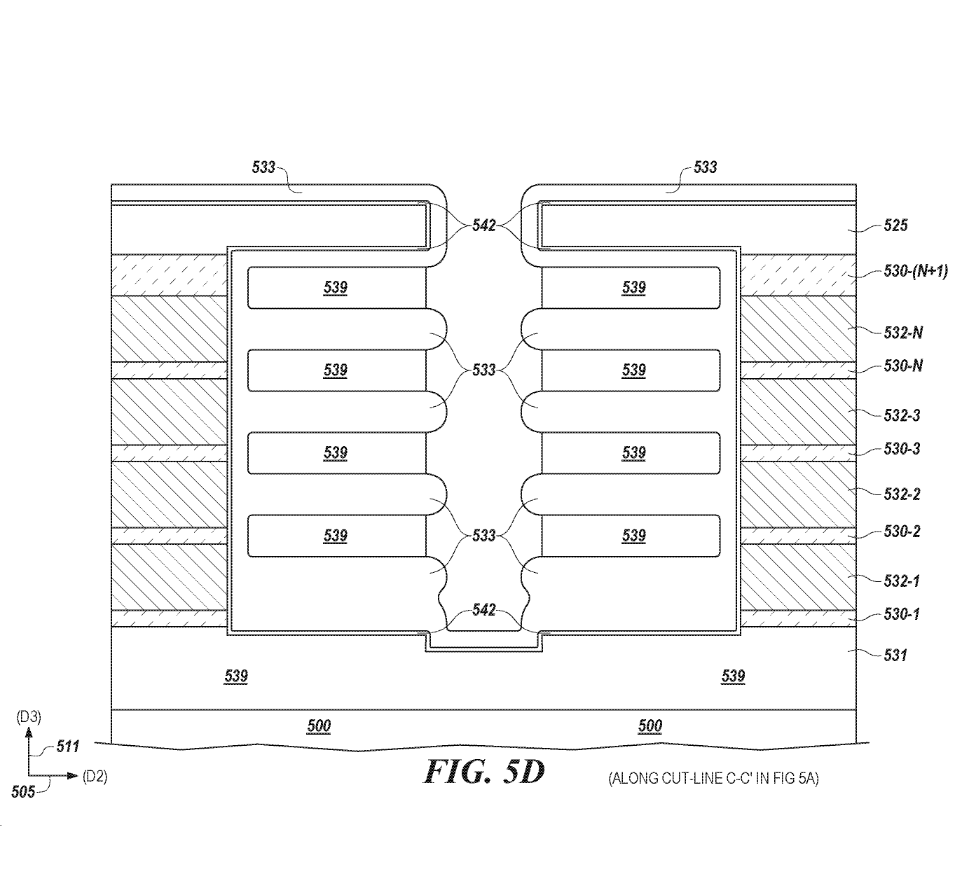

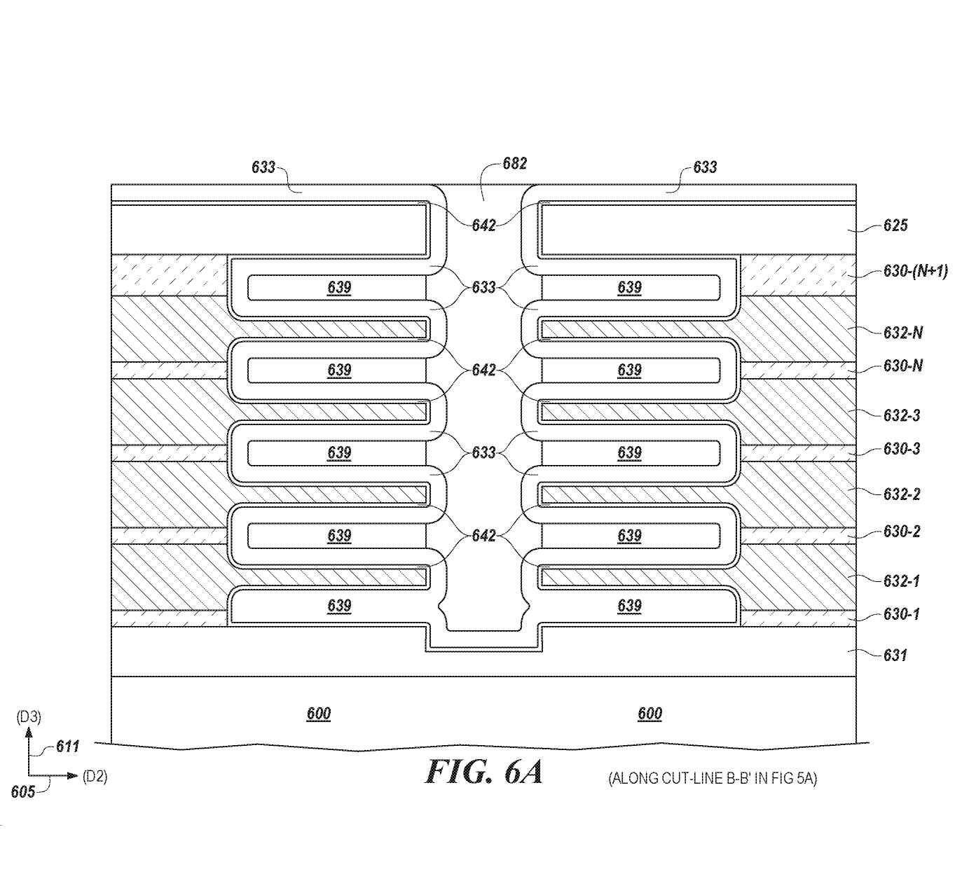

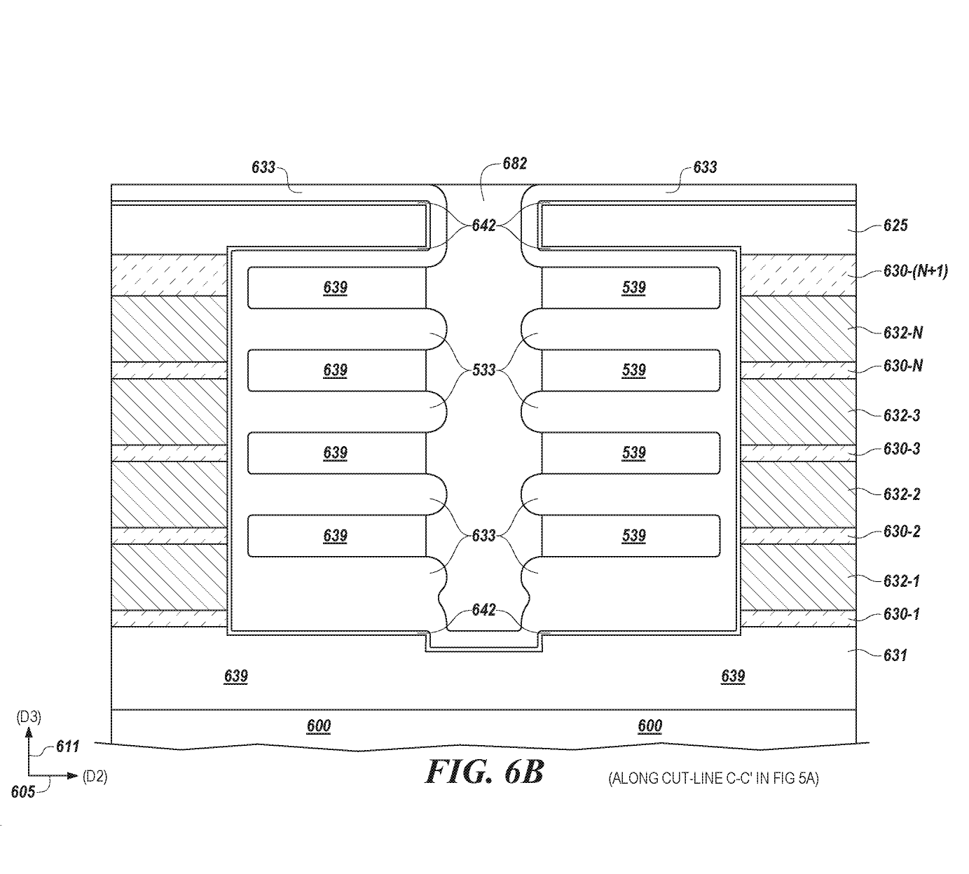

FIGS. 5A to 5B illustrate an example method, at one stage of a semiconductor fabrication process, for epitaxial digit line growth in vertical three-dimensional (3D) memory, in accordance with a number of embodiments of the present disclosure.

FIG. 5A illustrates a top-down view of a semiconductor structure, at a particular point in time, in a semiconductor fabrication process, according to one or more embodiments. In the example embodiment shown in the example of FIG. 5A, the method comprises using an etchant process to form a plurality of vertical openings 515 (e.g., a plurality of second vertical openings), having a first horizontal direction (D1) 509 and a second horizontal direction (D2) 505, through the vertical stack to the substrate. In one example, as shown in FIG. 5A, the plurality of vertical openings 515 are extending predominantly in the second horizontal direction (D2) 505 and may form elongated vertical columns 513-1, 513-2, . . ., 513-M (collectively and/or independently referred to as 513), with sidewalls 514 in the vertical stack. The plurality of first vertical openings 500 may be formed using photolithographic techniques to pattern a photolithographic mask 535, e.g., to form a hard mask (HM), on the vertical stack prior to etching the plurality of first vertical openings 515. Similar semiconductor process techniques may be used at other points of the semiconductor fabrication process described herein.

FIG. 5B illustrates a cross-sectional view, taken along cut-line A-A’ in FIG. 5A, showing another view of the semiconductor structure at this particular point in one example semiconductor fabrication process of an embodiment of the present disclosure. The cross-sectional view shown in FIG. 5B is illustrated, right to left in the plane of the drawing sheet, extending in the first direction (D1) 509 along an axis of the repeating iterations of alternating layers of first dielectric material 539 and Si material 532 wrapped with a gate dielectric material 542. The gate dielectric material 542 may be conformally deposited fully around every surface of the Si material 532, to form gate all around (GAA) gate structures, at the channels of the access device regions. The Si material 532 may be surrounded by first conductive material formed on the gate dielectric material 542. The first conductive material may be conformally deposited fully around every surface of the Si material 532, to form gate all around (GAA) gate structures, at the channels of the access device regions.

FIG. 5C illustrates a cross-sectional view, taken along cut-line B-B’ in FIG. 5A, showing another view of the semiconductor structure at this particular point in one example semiconductor fabrication process of an embodiment of the present disclosure. The cross-sectional view in FIG. 5C is illustrated, right to left in the plane of the drawing sheet, extending in the second direction (D2) 505 along an axis of the repeating iterations of alternating layers of first dielectric material 539 and Si material 532 wrapped with a gate dielectric material 542.

As shown in FIG. 5C, a plurality of vertical openings may be formed through the layers within the vertically stacked memory cells to expose vertical sidewalls in the vertical stack and then filled with a first dielectric material 539. The vertical openings may be formed through the repeating iterations of the silicon germanium (SiGe) 530 and the silicon (Si) material 532.

A first dielectric material 539, such as an oxide or other suitable spin on dielectric (SOD), may be deposited in the vertical openings, using a process such as CVD, to fill the vertical openings. First dielectric material 539 may also be formed from a silicon nitride (Si3N4) material. In another example, the first dielectric material 539 may include silicon oxy-nitride (SiOxNy), and/or combinations thereof. Embodiments are not limited to these examples. The plurality of first vertical openings may be formed using photolithographic techniques to pattern a photolithographic mask, e.g., to form a hard mask (HM), on the vertical stack prior to etching the plurality of first vertical openings. In one embodiment, hard mask may be deposited over silicon germanium (SiGe) 530. Similar semiconductor process techniques may be used at other points of the semiconductor fabrication process described herein.

The semiconductor fabrication process can further include selectively etching the silicon germanium (SiGe) 530 isotropically to form a plurality of first horizontal openings in the first region separating layers of the Si material 532. An etchant may be flowed into the second vertical opening 515 to selectively etch a portion of the epitaxially grown silicon germanium (SiGe) 530 within the stack. As such, the etchant may target the first silicon germanium (SiGe) 530-1, the second silicon germanium (SiGe) 530-2, and the third silicon germanium (SiGe) 530-3 within the stack. The selective etchant process may etch the silicon germanium (SiGe) 530 to form the plurality of first horizontal openings.

The selective etchant process may comprise a selective etch chemistry of phosphoric acid (H3PO4) or hydrogen fluoride (HF) and/or dissolving the silicon germanium (SiGe) 530 using a selective solvent, among other possible etch chemistries or solvents. Alternatively, or in addition, a selective etch to remove the silicon germanium (SiGe) 530 may consist of one or more etch chemistries selected from an aqueous etch chemistry, a semi-aqueous etch chemistry, a vapor etch chemistry, or a plasma etch chemistries, among other possible selective etch chemistries. For example, a dry etch chemistry of oxygen (O2) or O2 and sulfur dioxide (SO2) may be utilized. As another example, a dry etch chemistries of O2 or of O2 and nitrogen (N2) may be used to selectively etch the silicon germanium (SiGe) 530.

The semiconductor fabrication process can further include forming a gate dielectric material on exposed surfaces of the reduced vertical thickness of the Si material 532. For example, a gate dielectric material 542 may be formed on exposed surfaces of the Si material 532 to form horizontal access devices. In some embodiments the gate dielectric material may be an oxide material 542. The gate dielectric material 542 may be conformally deposited fully around every surface of the Si material 532 to form gate all around (GAA) gate structures, at the channels of the access device regions. The gates at the channel regions provide a subthreshold voltage (sub-Vt) slope in a range of approximately 45 to 100 millivolts per decade (mV/dec).

The gate dielectric material 542 may be deposited on exposed surfaces of the Si material 532 using an atomic layer deposition. In some embodiments the gate dielectric material may be an oxide material. For example, an oxide material may be deposited over the exposed surfaces of the epitaxially grown, single crystalline silicon (Si) material 532 to prevent oxidization of the Si material 532. The oxide material deposition may prevent shorts by protecting the Si material 532 from interactions with the first dielectric material 539. The oxide material may be selectively deposited on exposed surfaces of the Si material 532 using atomic layer deposition. A thermal oxidation process may be used to densify the ALD deposited oxide material. The thermal oxidation process involves forming oxide material from a hybrid oxide material. The hybrid oxide material may combine a low temperature oxide material and a high temperature oxide material.

The silicon germanium (SiGe) 530 has now been selectively etched isotropically to form a plurality of first horizontal openings in the first region separating layers of the Si material 532. A second dielectric material 533 may be conformally deposited all around first horizontal opening. The second dielectric material 533 may be deposited fully around exposed surfaces in the plurality of first horizontal openings. The second dielectric material 533 may serve as a liner around the plurality of first horizonal openings. The second dielectric material 533 may be flowed into the vertical opening to cover exposed surfaces of the Si material where the SiGe was removed to form the plurality of first horizontal openings within the stack.

In one embodiment, the second dielectric material 533 may comprise a nitride material. In another embodiment, second dielectric material 533 may comprise a silicon nitride (Si3N4) material (also referred to herein as “SiN”). In another embodiment the second dielectric material 533 may include silicon dioxide (SiO2) material. In another embodiment the second dielectric material 533 may comprise a silicon oxy-carbide (SiOxCy) material, and/or combinations thereof. Embodiments are not limited to these examples.

In one embodiment, the second dielectric material 533 may be conformally deposited all around exposed surfaces in the plurality of first horizontal openings to have a thickness (t1) of approximately 100 to 300 angstroms (Å). Embodiments, however, are not limited to these examples.

The semiconductor fabrication process can further include depositing the first dielectric material 539 to full the plurality of first horizontal openings. For example, a first dielectric material 539, such as an oxide or other suitable spin on dielectric (SOD), is deposited into the plurality of first horizontal openings, on the exposed surfaces of the second dielectric material 533, to fill the first horizontal openings. The first dielectric material 539 may entirely or substantially fill the plurality of first horizontal openings. The first dielectric material 539 may be flowed into the vertical openings to fill the vertical openings and to fill the plurality of first horizontal openings within the stack. As such, the first dielectric material 539 may fill the first horizontal openings within the first silicon germanium (SiGe) 530-1, the second silicon germanium (SiGe) 530-2, and the third silicon germanium (SiGe) 530-3 within the stack.

The semiconductor fabrication process can further include selectively etching the second dielectric material 533 from the plurality of first horizontal openings a second length (L2) from the vertical openings. An etchant may be flowed into the vertical opening to selectively etch a portion of the second dielectric material 530 within the stack. As such, the etchant may target the second dielectric material 530 within the stack. The selective etchant process may etch the second dielectric material 530 the second length L2. Any selective etch chemistry described herein or otherwise may be utilized for such a selective etchant process.

FIG. 5D illustrates a cross-sectional view, taken along cut-line C-C’ in FIG. 5A, showing another view of the semiconductor structure at this particular point in one example semiconductor fabrication process of an embodiment of the present disclosure. The cross-sectional view in FIG. 5D is illustrated, right to left in the plane of the drawing sheet, extending in the second direction (D2) 505 along an axis of the repeating iterations of alternating layers of first dielectric material 539 and Si material 532 wrapped with a gate dielectric material 542.

As shown in FIG. 5D, the vertical opening in the stack consists of a gate dielectric material 542 wrapping the alternating layers of SiGe material 530 and Si material 532. Additionally, located in the vertical opening are alternating layers of second dielectric material 533 and first dielectric material 539. At this point in the semiconductor fabrication process, a plurality of spaced vertical columns adjacent to the first source/drain regions can be formed, and a plurality of spaced vertical digit lines can be formed between the plurality of spaced vertical columns, as is further described herein.

FIGS. 6A to 6B illustrate an example method, at one stage of a semiconductor fabrication process, for digit line formation in vertical three-dimensional (3D) memory, in accordance with a number of embodiments of the present disclosure.

FIG. 6A illustrates a cross-sectional view, taken along cut-line A-A’ in FIG. 5A, showing another view of the semiconductor structure at this particular point in one example semiconductor fabrication process of an embodiment of the present disclosure. The cross-sectional view shown in FIG. 6A is illustrated, right to left in the plane of the drawing sheet, extending in the second direction (D2) 605.

The semiconductor fabrication process can include depositing a sacrificial dielectric material 682 in the vertical opening to fill the vertical opening. The sacrificial dielectric material 682 may entirely or substantially fill the first vertical opening. The sacrificial dielectric material 682 can be flowed into the vertical opening to fill the vertical opening in the stack.

In some examples, the sacrificial dielectric material 682 can be carbon. However, embodiments of the disclosure are not so limited. For example, the sacrificial dielectric material 682 can be any other dielectric material.

The sacrificial dielectric material 682 may be deposited in the vertical opening via chemical vapor deposition. Embodiments, however, are not limited to this example and other suitable semiconductor fabrication techniques may be used to deposit the sacrificial dielectric material 682.

FIG. 6B illustrates a cross-sectional view, taken along cut-line C-C’ in FIG. 5A, showing another view of the semiconductor structure at this particular point in one example semiconductor fabrication process of an embodiment of the present disclosure. The cross-sectional view shown in FIG. 6B is illustrated, right to left in the plane of the drawing sheet, extending in the second direction (D2) 605. As illustrated in FIG. 6B, a sacrificial dielectric material 682 is deposited in the vertical opening to fill or substantially fill the vertical opening.

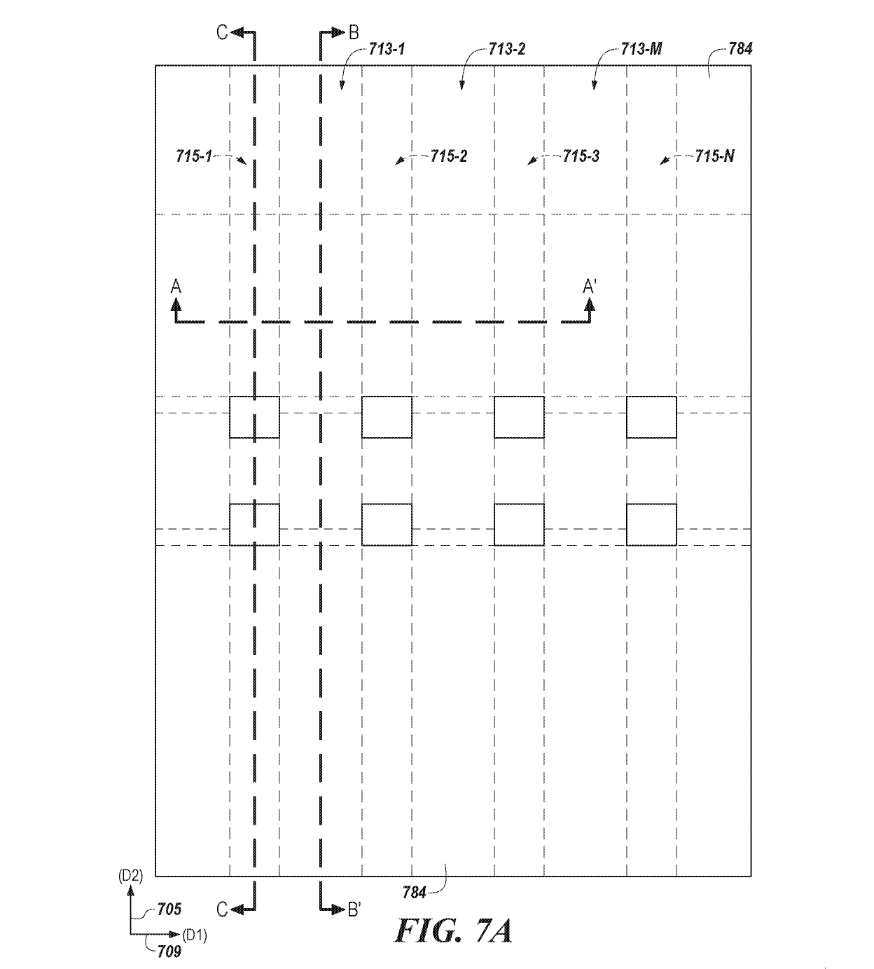

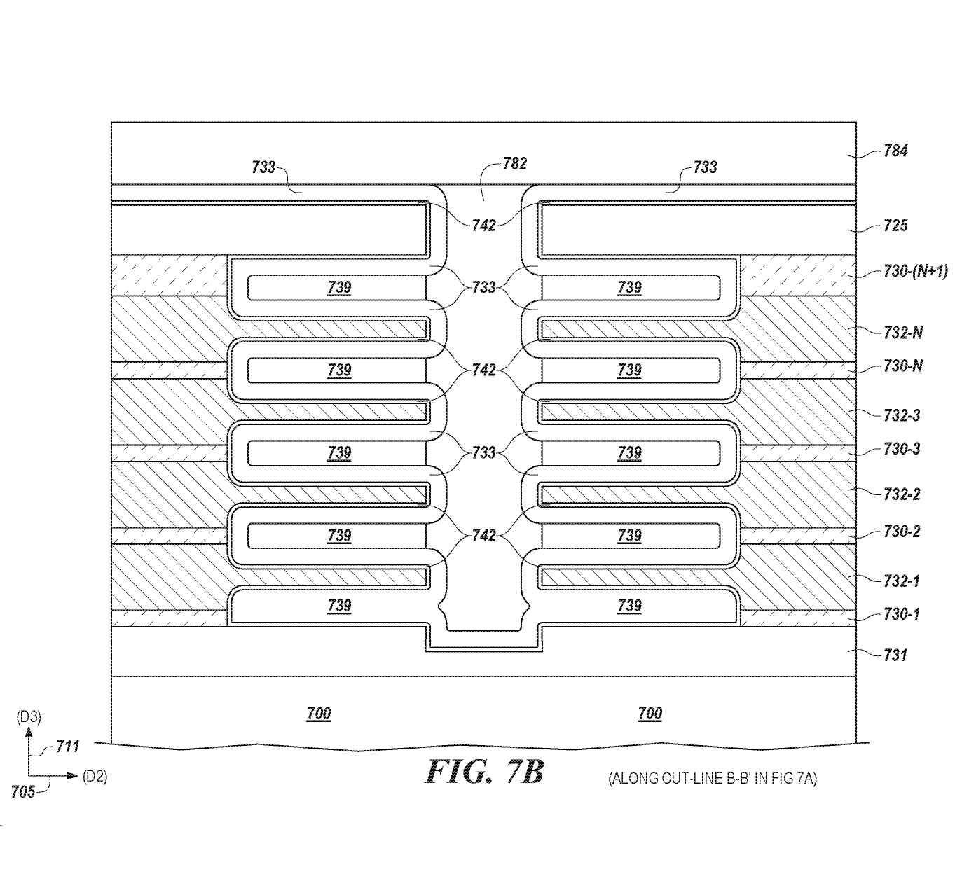

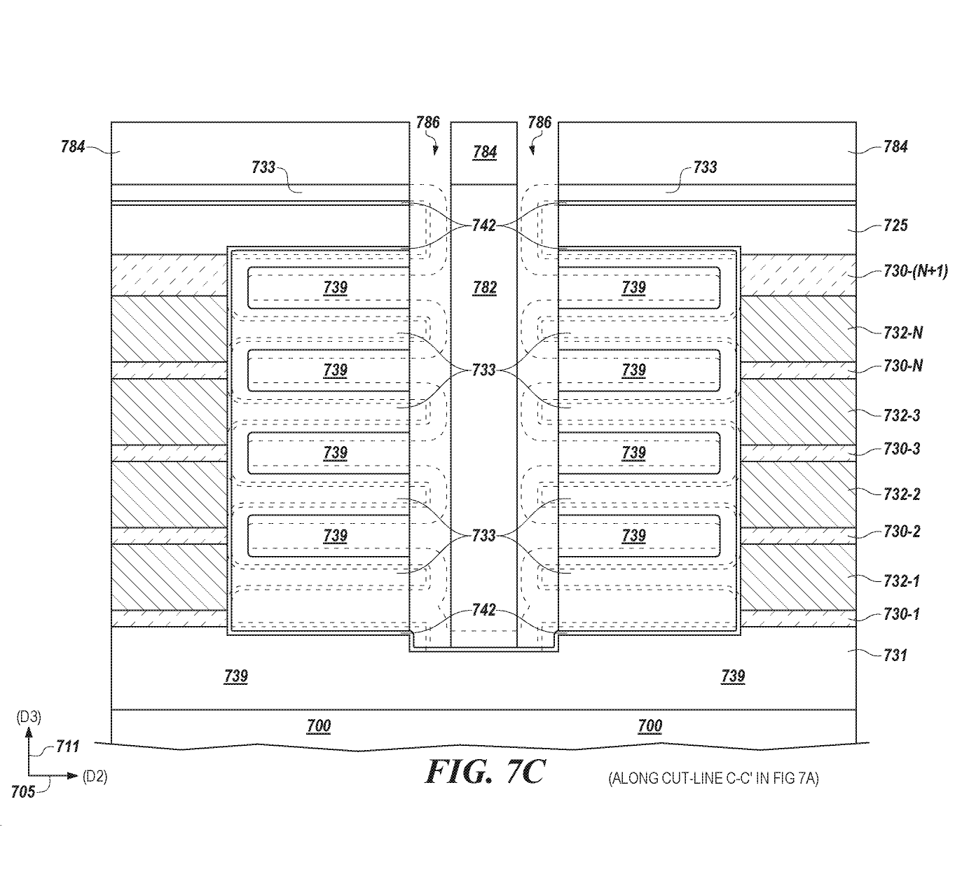

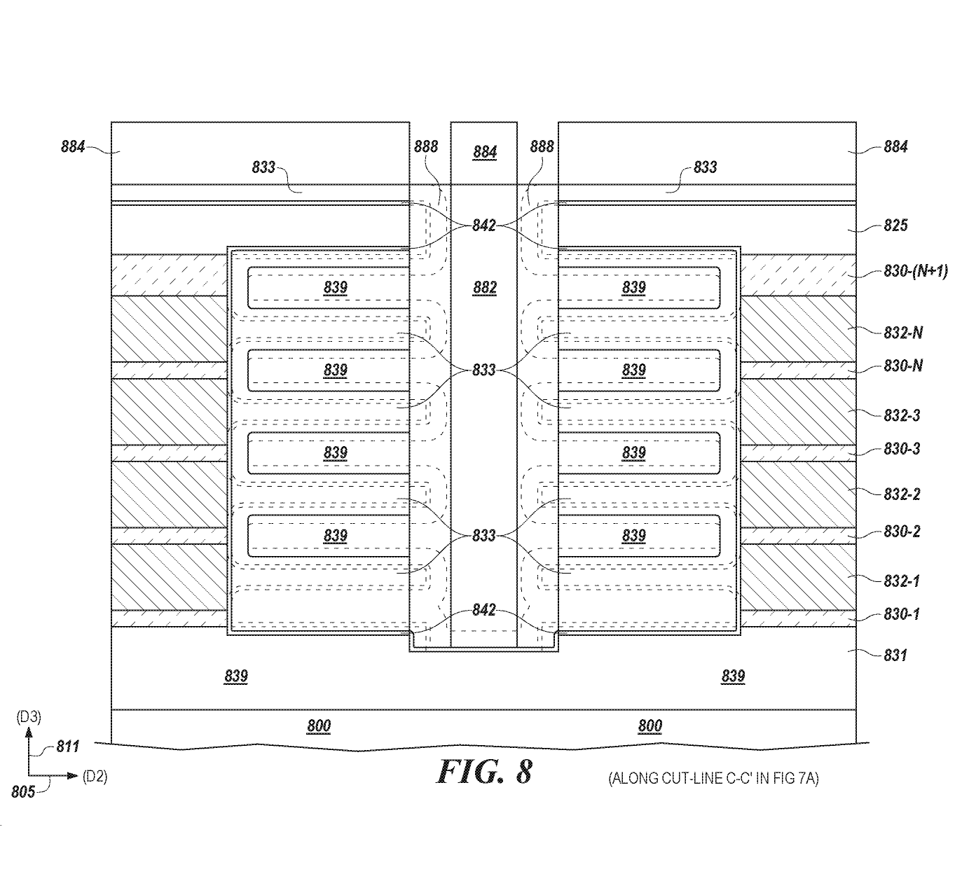

FIGS. 7A to 7C illustrate an example method, at one stage of a semiconductor fabrication process, for digit line formation in vertical three-dimensional (3D) memory, in accordance with a number of embodiments of the present disclosure.

FIG. 7A illustrates a top-down view of a semiconductor structure, at a particular point in time, in a semiconductor fabrication process, according to one or more embodiments. In the example embodiment shown in the example of FIG. 7A, the method comprises patterning a mask 784 on a top surface of the vertical stack. The mask 784 may be formed using photolithographic techniques, as is further described herein.

FIG. 7B illustrates a cross-sectional view, taken along cut-line B-B’ in FIG. 5A, showing another view of the semiconductor structure at this particular point in one example semiconductor fabrication process of an embodiment of the present disclosure. The cross-sectional view shown in FIG. 7B is illustrated, right to left in the plane of the drawing sheet, extending in the second direction (D2) 705.

As illustrated in FIG. 7B, the semiconductor fabrication process includes patterning a mask 784 on a top surface of the vertical stack. The mask 784 can be patterned as a photolithographic mask (e.g., to form a hard mask) on the vertical stack. The mask 784 can be patterned over the second dielectric material 733 and over the sacrificial dielectric material 782. In some embodiments, the mask 784 can be deposited on the top surface of the vertical stack using CVD and planarized using chemical mechanical planarization (CMP).

FIG. 7C illustrates a cross-sectional view, taken along cut-line C-C’ in FIG. 7A, showing another view of the semiconductor structure at this particular point in one example semiconductor fabrication process of an embodiment of the present disclosure. The cross-sectional view shown in FIG. 7C is illustrated, right to left in the plane of the drawing sheet, extending in the second direction (D2) 705. As illustrated in FIG. 7C, a mask 784 has been deposited on a top surface of the vertical stack.

The semiconductor fabrication process can include selectively removing portions of the sacrificial dielectric material 782 in the vertical opening. For example, a selective etch process can be utilized to selectively remove portions of the sacrificial dielectric material 782. An etchant may be flowed into the vertical opening (e.g., directed by the hard mask 784) to selectively etch portions of the sacrificial dielectric material 782.

The selective etchant process may comprise a selective etch chemistry of phosphoric acid (H3PO4) or hydrogen fluoride (HF) and/or dissolving the sacrificial dielectric material 782 using a selective solvent, among other possible etch chemistries or solvents. Alternatively, or in addition, a selective etch to remove the sacrificial dielectric material 782 may consist of one or more etch chemistries selected from an aqueous etch chemistry, a semi-aqueous etch chemistry, a vapor etch chemistry, or a plasma etch chemistries, among other possible selective etch chemistries. For example, a dry etch chemistry of oxygen (O2) or O2 and sulfur dioxide (SO2) may be utilized. As another example, a dry etch chemistries of O2 or of O2 and nitrogen (N2) may be used to selectively etch the sacrificial dielectric material 782.

As a result, the selective etch can remove portions of the sacrificial dielectric material 782, forming a plurality of spaced vertical openings 786. The plurality of spaced vertical openings 786 can be patterned openings in the vertical opening of the stack. The plurality of spaced vertical openings 786 can be utilized to form vertical columns to separate and electrically isolate digit lines, as is further described herein.

FIG. 8 illustrates an example method, at one stage of a semiconductor fabrication process, for digit line formation in vertical three-dimensional (3D) memory, in accordance with a number of embodiments of the present disclosure. FIG. 8 illustrates a cross-sectional view, taken along cut-line C-C’ in FIG. 5A, showing another view of the semiconductor structure at this particular point in one example semiconductor fabrication process of an embodiment of the present disclosure. The cross-sectional view shown in FIG. 8 is illustrated, right to left in the plane of the drawing sheet, extending in the second direction (D2) 805. As illustrated in FIG. 8, a mask 884 has been deposited on a top surface of the vertical stack and portions of the sacrificial dielectric material 882 have been selectively etched and removed from the vertical opening to form a plurality of spaced vertical openings.

The semiconductor fabrication process can include forming a plurality of spaced vertical columns 888 adjacent to the first source/drain regions. For example, the method includes depositing a selectively etchable dielectric fill material in the plurality of spaced vertical openings to form the plurality of spaced vertical columns 888. In some examples, the selectively etchable dielectric fill material can be a high-k dielectric material that forms the plurality of spaced vertical columns 888. The plurality of spaced vertical columns 888 will eventually be located between the plurality of spaced vertical digit lines, where the plurality of spaced vertical columns 888 can separate and electrically isolate adjacent ones of the spaced vertical digit lines, as is further described herein.

The high-k selectively etchable dielectric material may be deposited into the plurality of spaced vertical openings to fill the plurality of spaced vertical openings. A process such as CVD may be utilized to fill the plurality of spaced vertical openings with the high-k selectively etchable dielectric material, although embodiments of the disclosure are not limited to CVD. As illustrated in the semiconductor fabrication process so far, the plurality of spaced vertical columns 888 can be formed prior to forming the horizontally oriented storage nodes, as is further described herein.

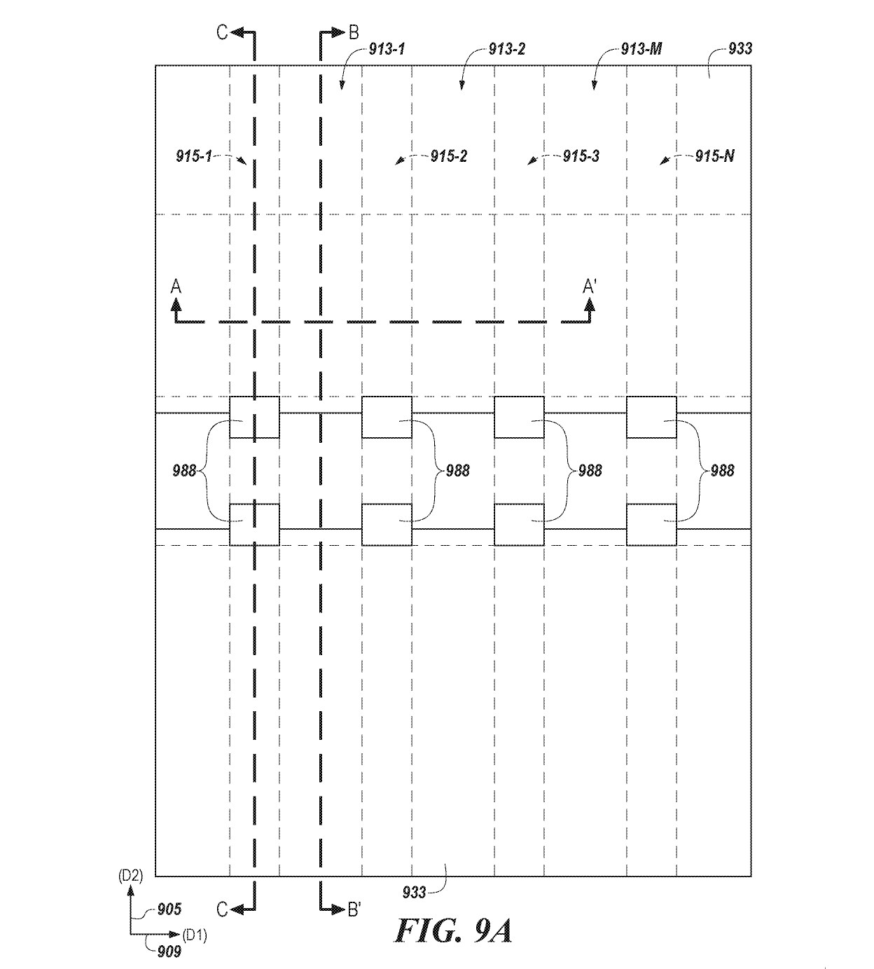

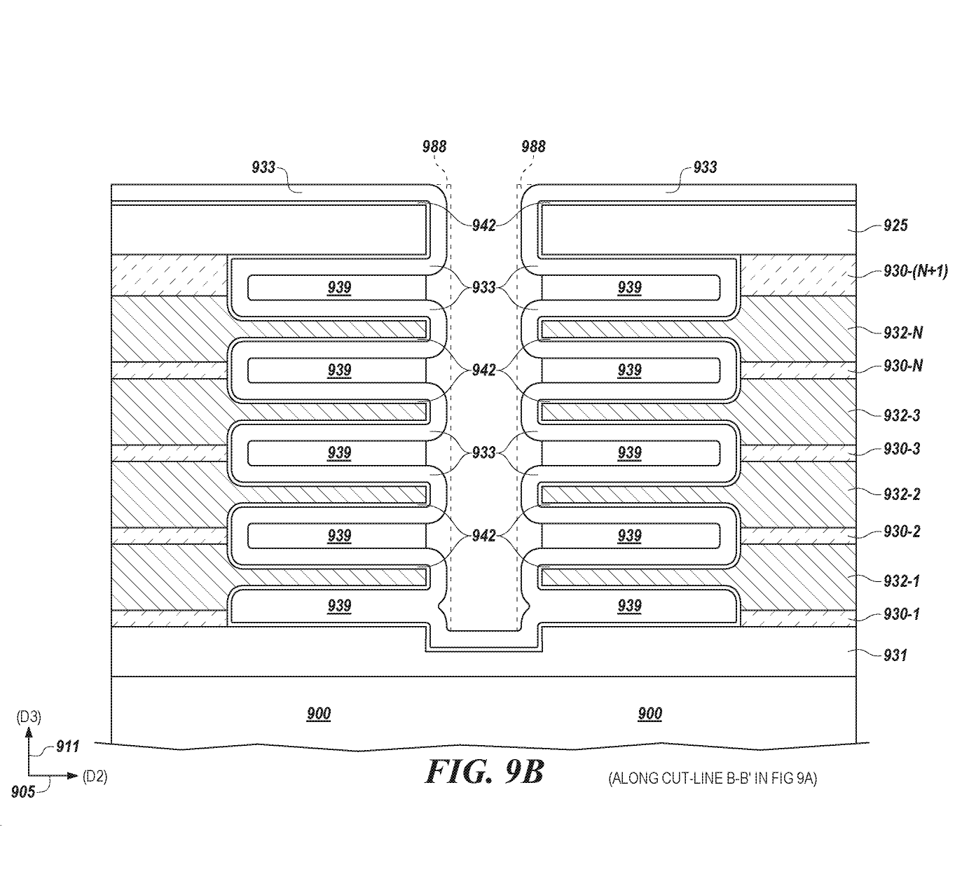

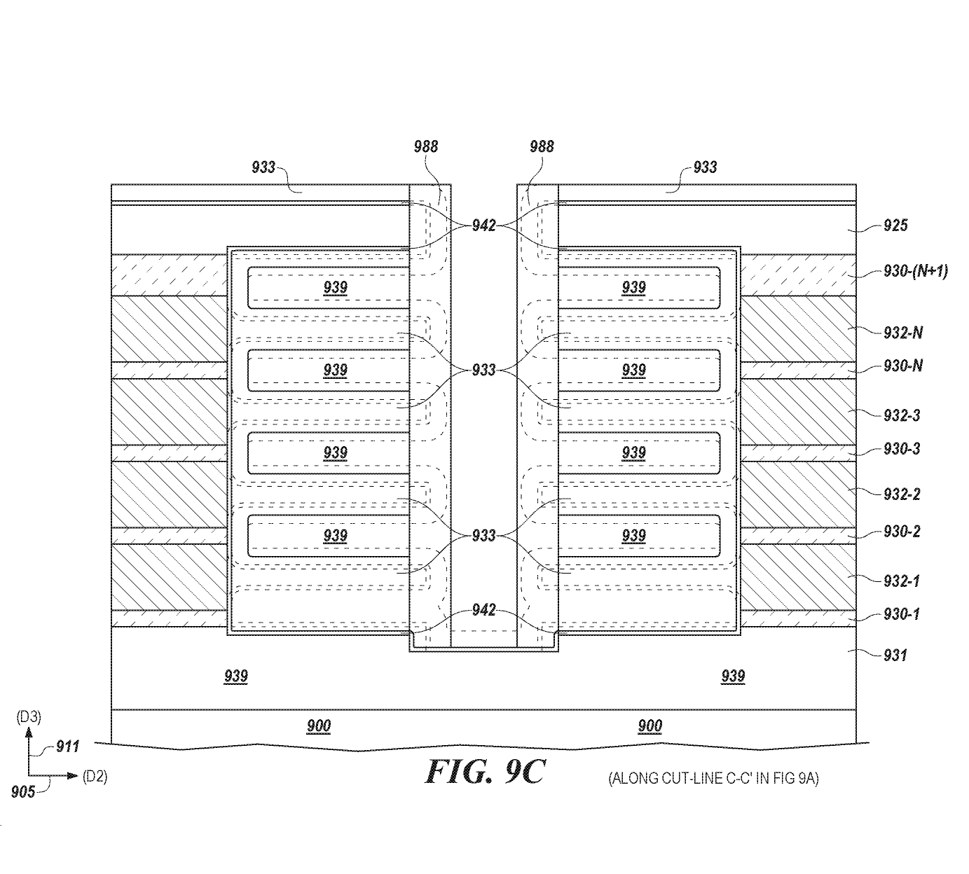

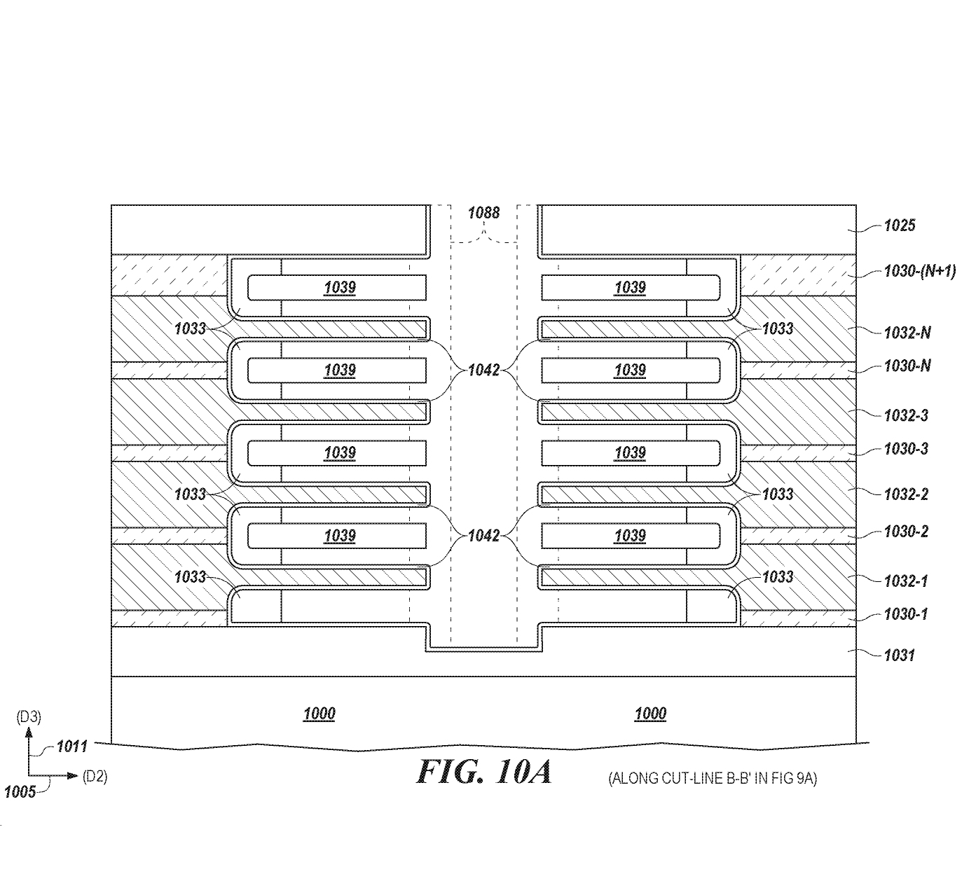

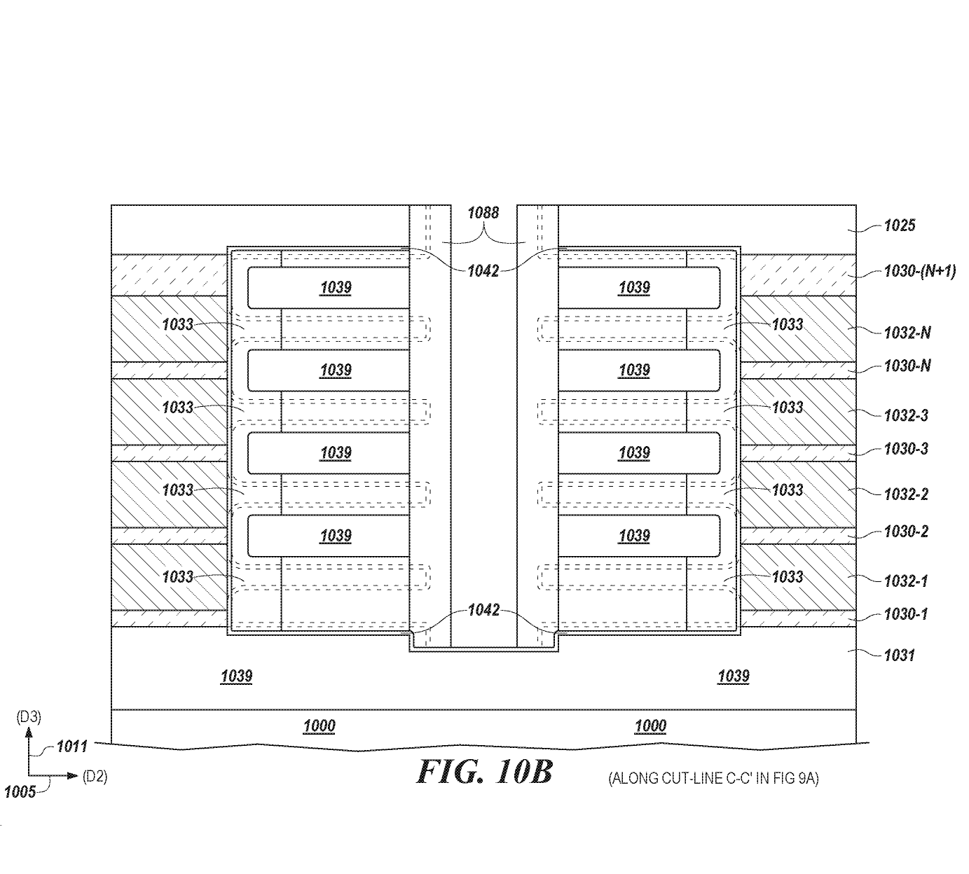

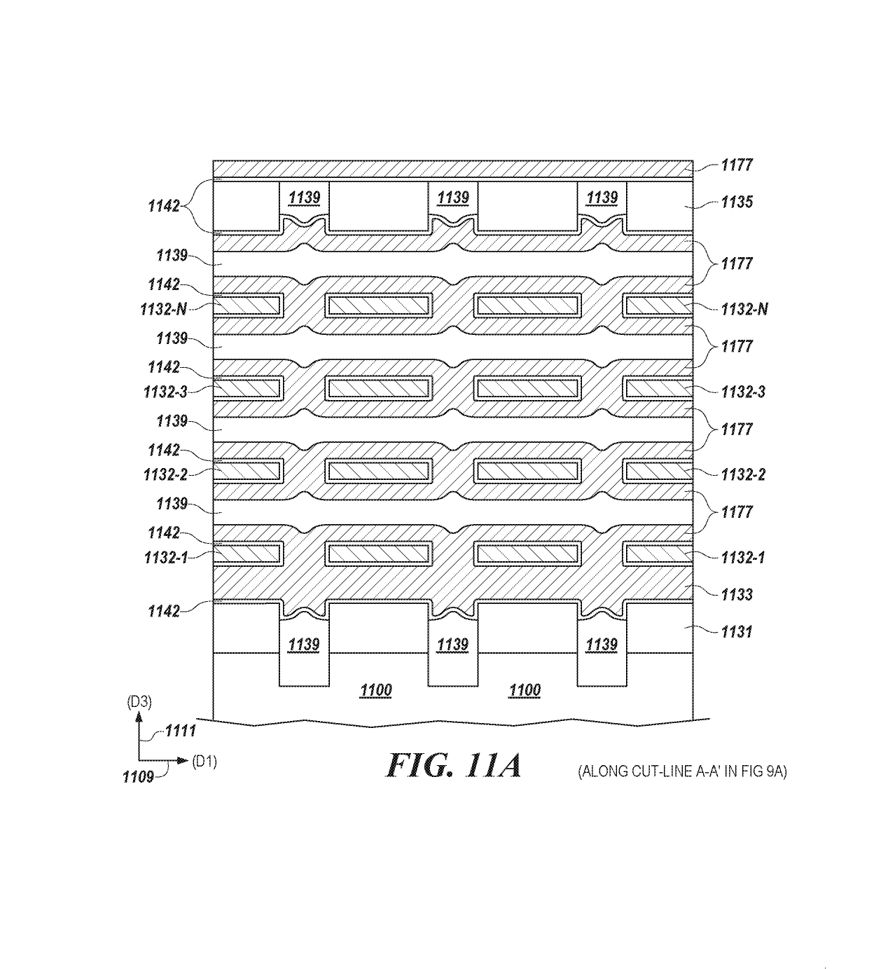

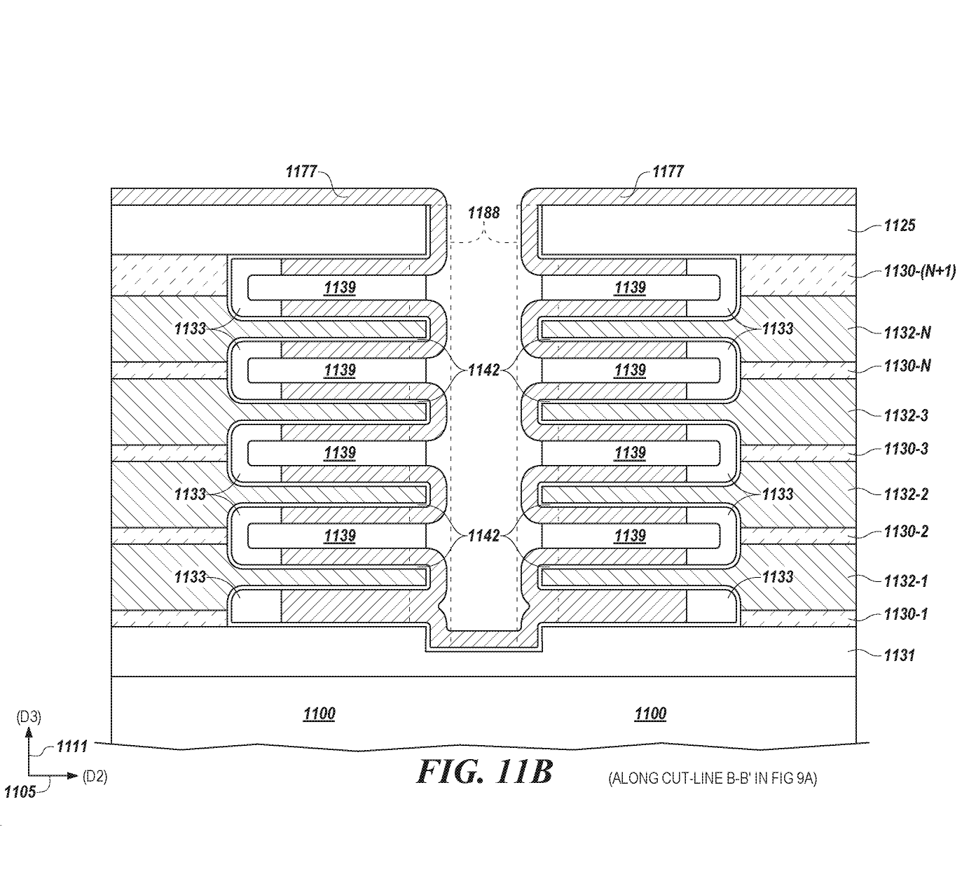

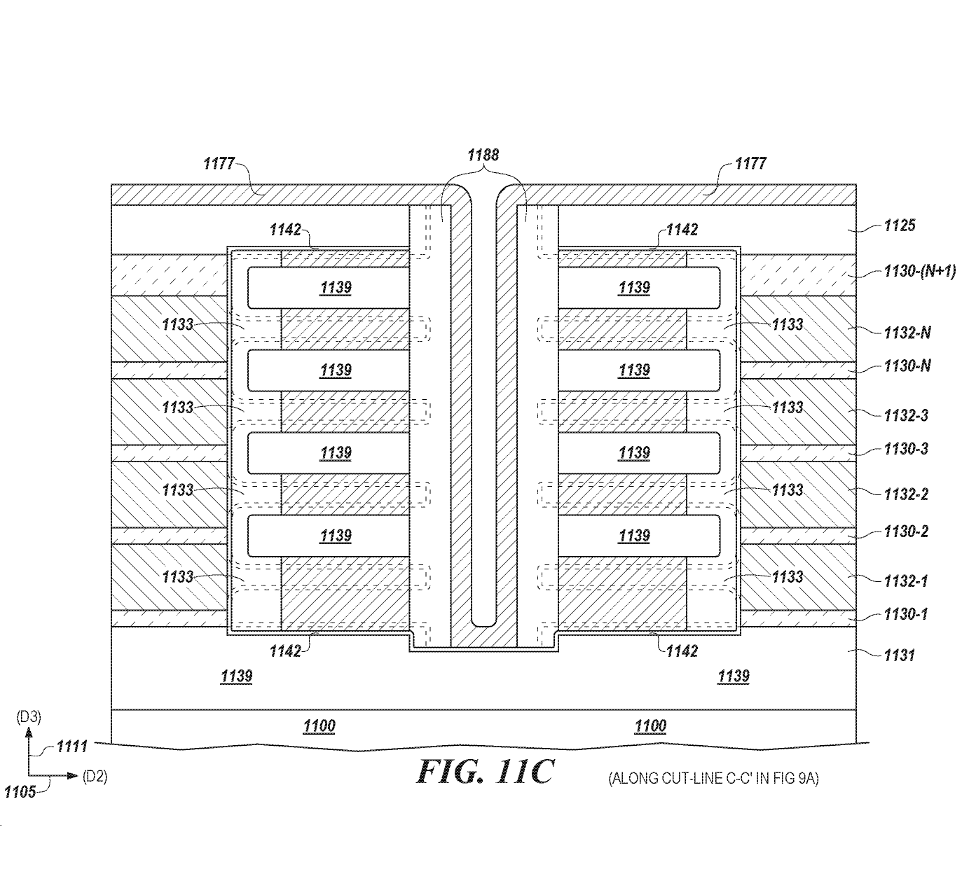

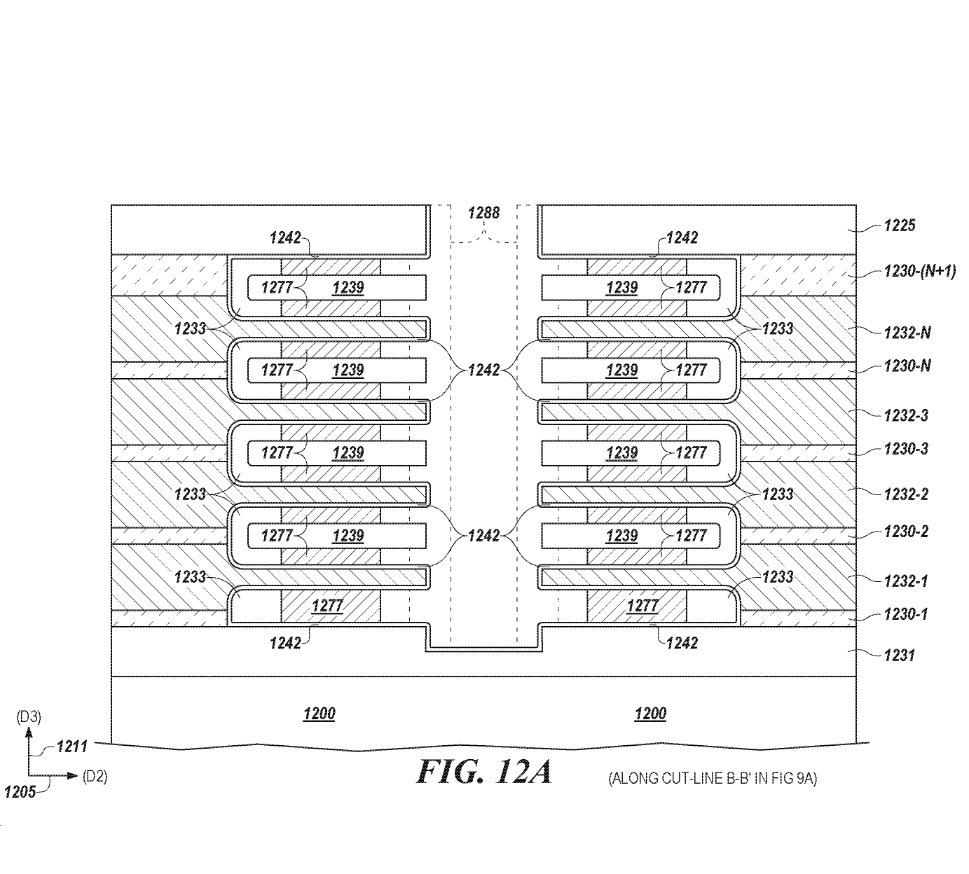

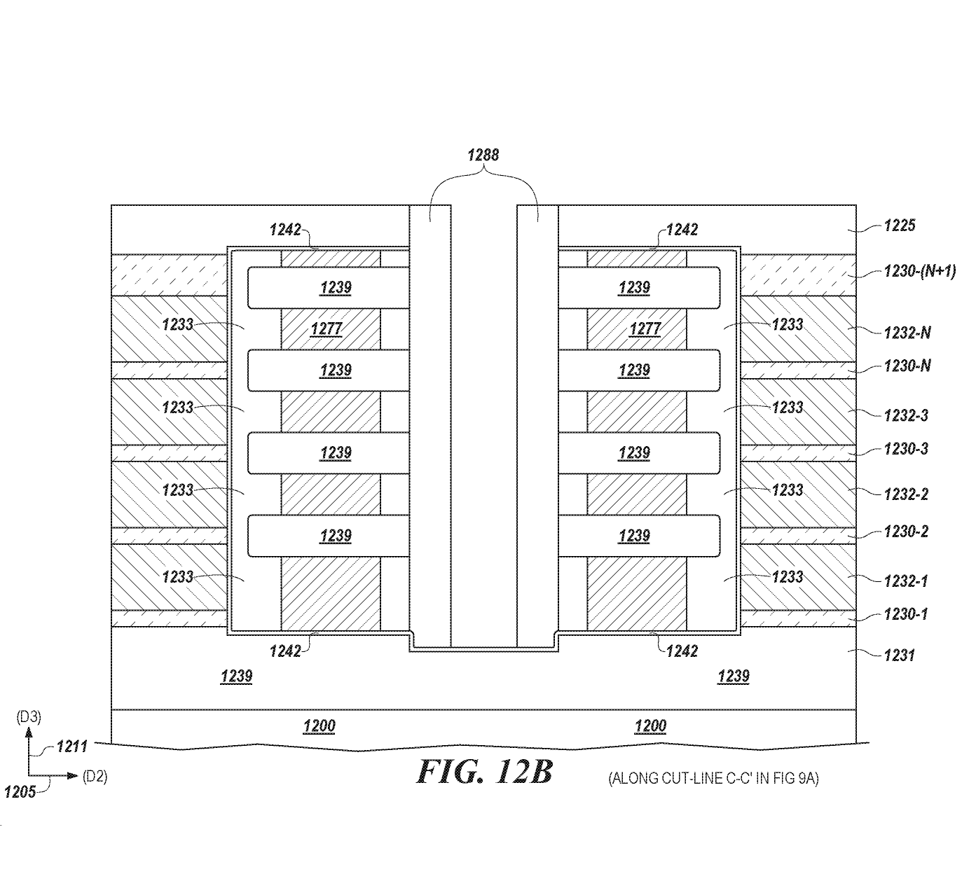

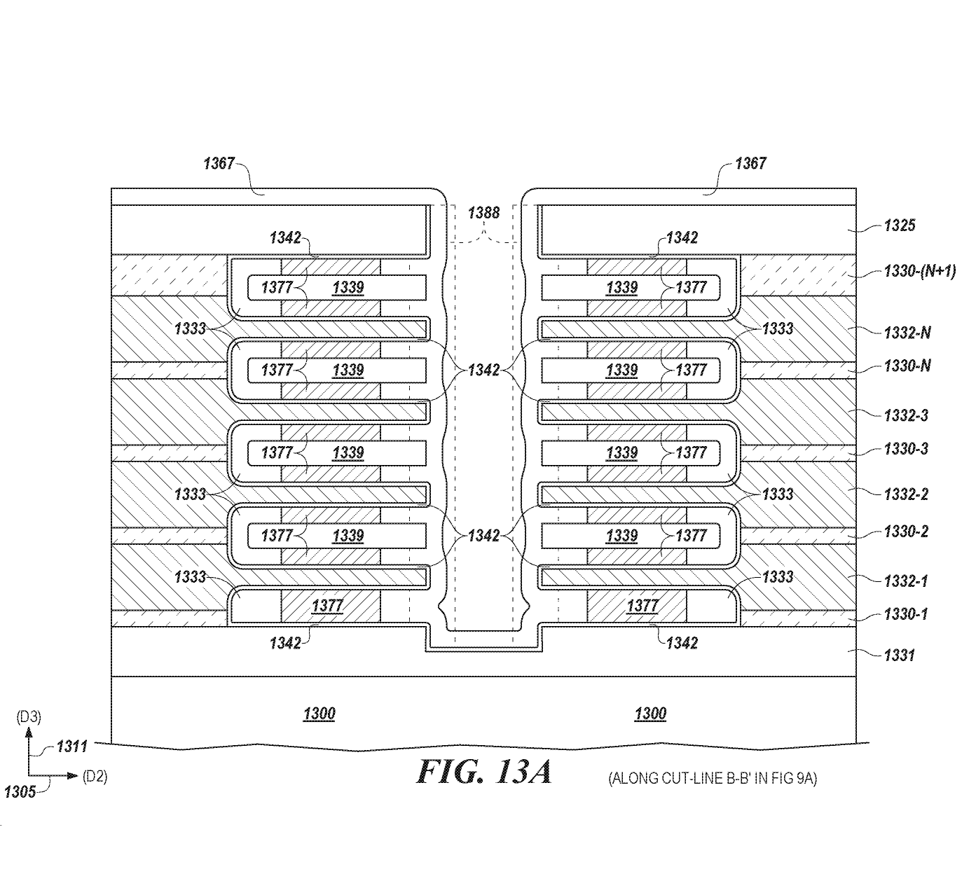

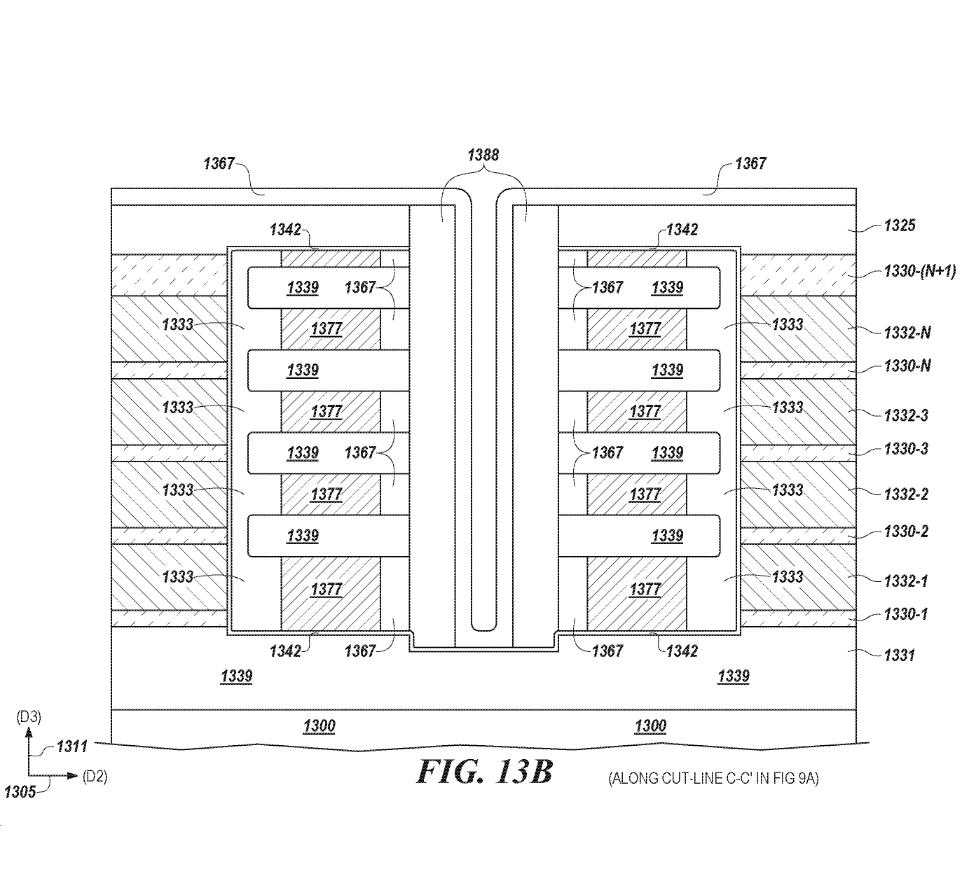

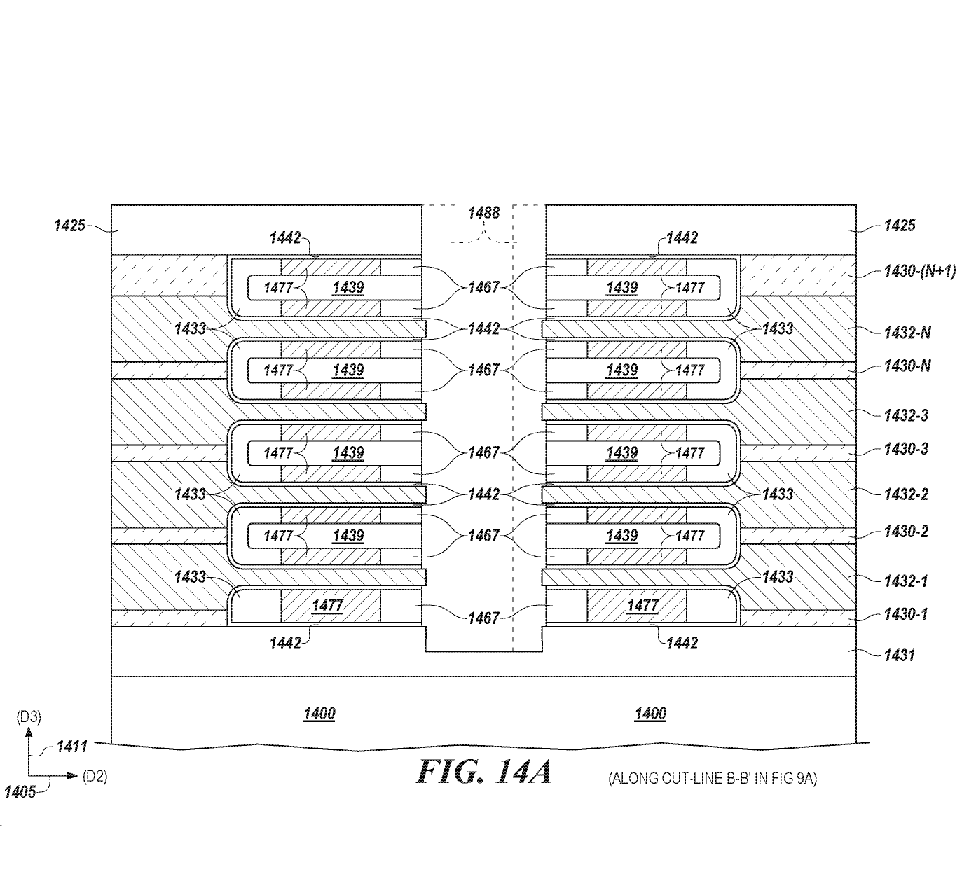

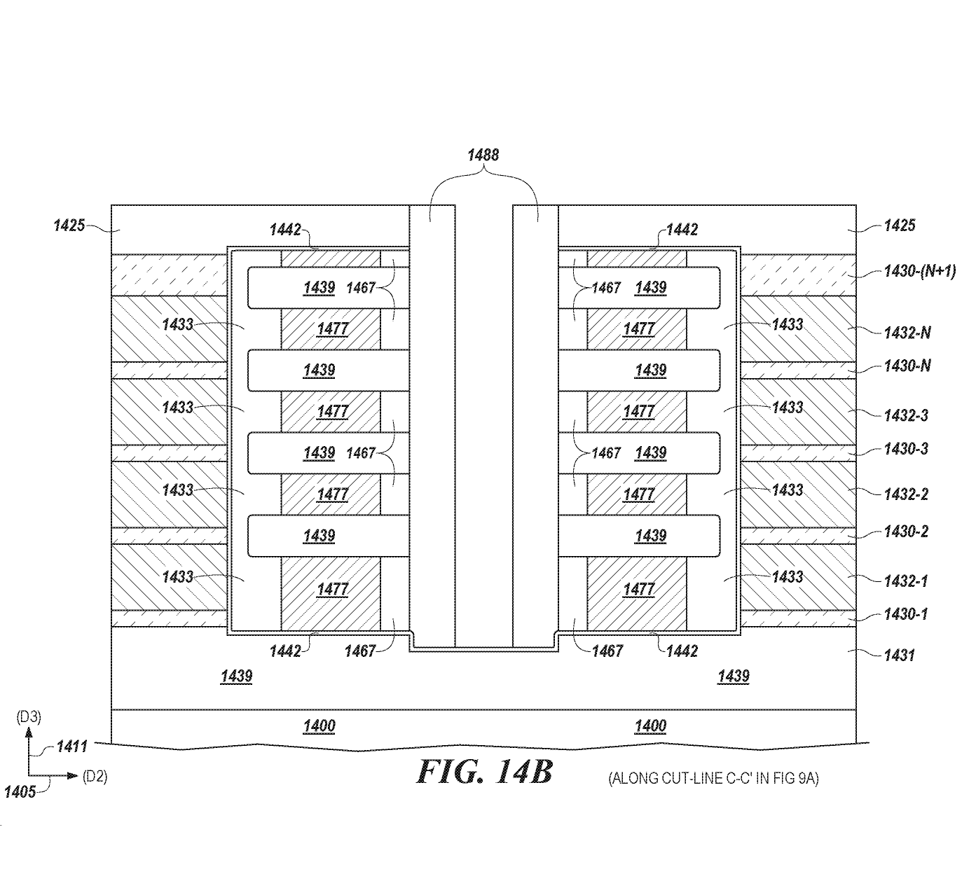

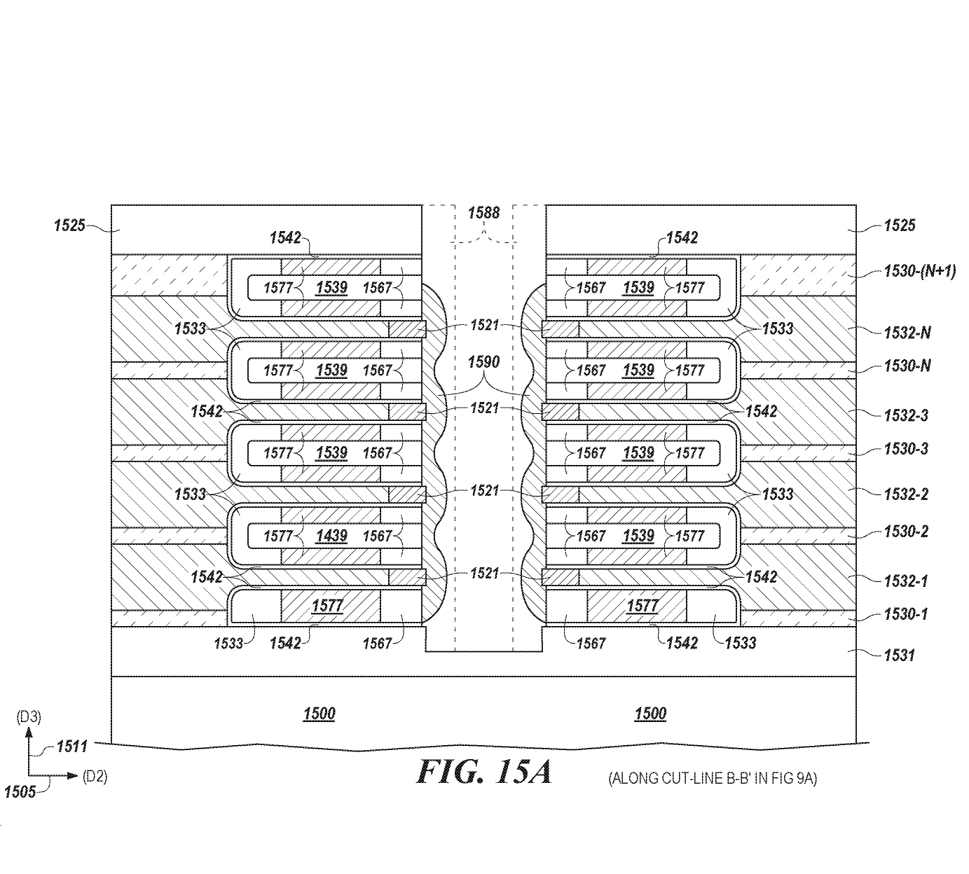

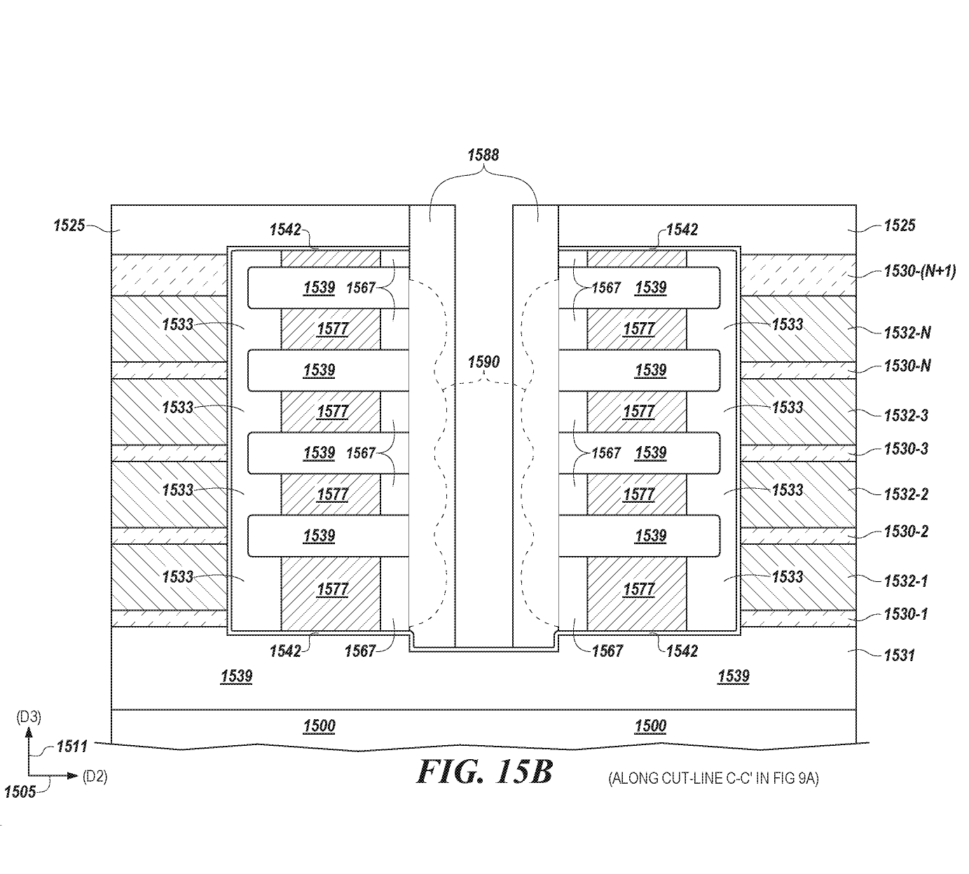

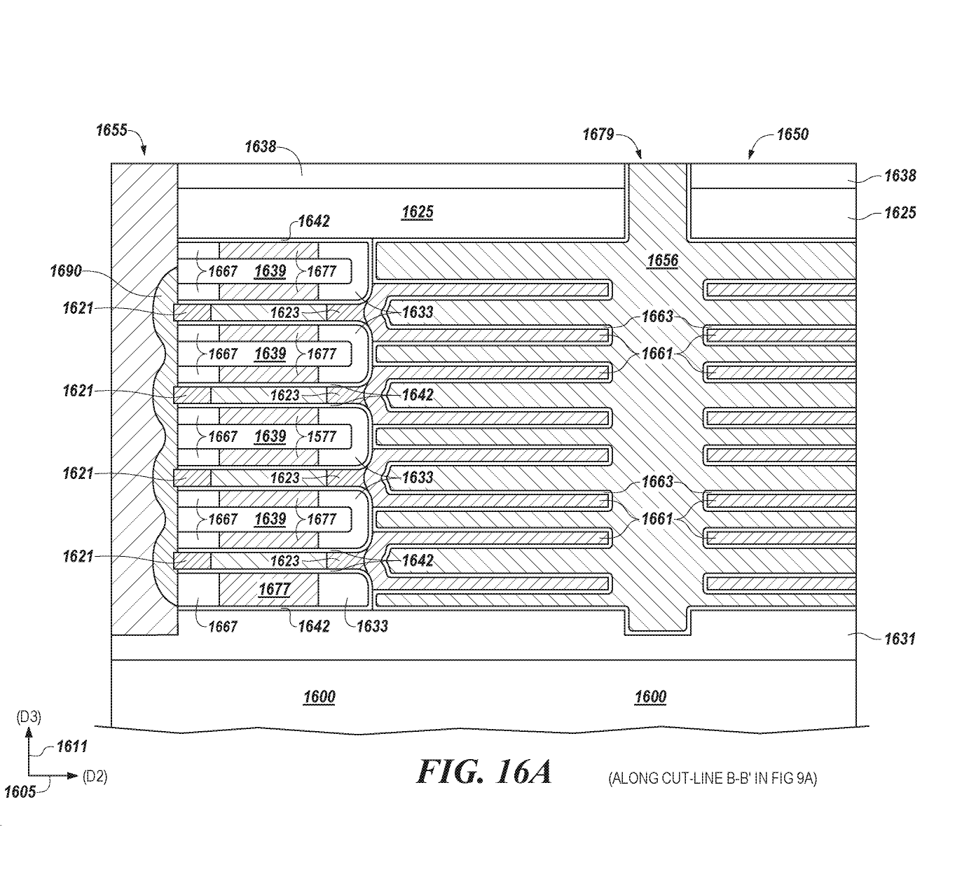

FIGS. 9A to 9C illustrate an example method, at one stage of a semiconductor fabrication process, for digit line formation in vertical three-dimensional (3D) memory, in accordance with a number of embodiments of the present disclosure.

FIG. 9A illustrates a top-down view of a semiconductor structure, at a particular point in time, in a semiconductor fabrication process, according to one or more embodiments. In the example embodiment shown in the example of FIG. 9A, a plurality of spaced vertical columns 988 have been formed in the vertical opening adjacent to the first source/drain regions.

FIG. 9B illustrates a cross-sectional view, taken along cut-line B-B’ in FIG. 9A, showing another view of the semiconductor structure at this particular point in one example semiconductor fabrication process of an embodiment of the present disclosure. The cross-sectional view shown in FIG. 9B is illustrated, right to left in the plane of the drawing sheet, extending in the second direction (D2) 905.

The semiconductor fabrication process includes removing the sacrificial dielectric material from the vertical opening. In some examples, the sacrificial dielectric material can be selectively etched from the vertical opening. An etchant may be flowed into the vertical opening to selectively etch the sacrificial dielectric material. As such, the etchant may target the sacrificial dielectric material within the vertical opening. Removing the sacrificial dielectric material from the vertical opening defines a void in the first vertical opening, the void including the plurality of spaced vertical columns 988 in the first vertical opening without the sacrificial dielectric material.

FIG. 9C illustrates a cross-sectional view, taken along cut-line C-C’ in FIG. 9A, showing another view of the semiconductor structure at this particular point in one example semiconductor fabrication process of an embodiment of the present disclosure. The cross-sectional view shown in FIG. 9C is illustrated, right to left in the plane of the drawing sheet, extending in the second direction (D2) 905. As illustrated in FIG. 9C, the sacrificial dielectric material from the vertical opening has been removed.

Accordingly, the plurality of spaced vertical columns 988 remain in the vertical opening. As illustrated in FIG. 9C, the second dielectric material 933 separates the plurality of spaced vertical columns 988 from a first conductive material of gate all around (GAA) structures in the 3D memory stack. The plurality of spaced vertical columns 988 can separate and electrically isolate vertical digit lines, as is further described herein.

FIGS. 10A to 10B illustrate an example method, at one stage of a semiconductor fabrication process, for digit line formation in vertical three-dimensional (3D) memory, in accordance with a number of embodiments of the present disclosure.

FIG. 10A illustrates a cross-sectional view, taken along cut-line B-B’ in FIG. 9A, showing another view of the semiconductor structure at this particular point in one example semiconductor fabrication process of an embodiment of the present disclosure. The cross-sectional view shown in FIG. 10A is illustrated, right to left in the plane of the drawing sheet, extending in the second direction (D2) 1005.

In the semiconductor fabrication process, the second dielectric material 1033 can be recessed in the vertical opening. The second dielectric material 1033 can be recessed a particular length. For example, the second dielectric material 1033 can be recessed away from the vertical opening.

In some embodiments, the second dielectric material 1033 may be etched using an atomic layer etching (ALE) process. In some embodiments, the second dielectric material 1033 may be etched using an isotropic etch process.

FIG. 10B illustrates a cross-sectional view, taken along cut-line C-C’ in FIG. 9A, showing another view of the semiconductor structure at this particular point in one example semiconductor fabrication process of an embodiment of the present disclosure. The cross-sectional view shown in FIG. 10B is illustrated, right to left in the plane of the drawing sheet, extending in the second direction (D2) 1005. As illustrated in FIG. 10B, the second dielectric material 1033 has been recessed.

As further illustrated in FIG. 10B, the plurality of spaced vertical columns 1088 remain in the vertical opening. The recessed second dielectric material 1033 separates the the plurality of spaced vertical columns 988 from a first conductive material of gate all around (GAA) structures in the 3D memory stack.

FIGS. 11A to 11C illustrate an example method, at one stage of a semiconductor fabrication process, for digit line formation in vertical three-dimensional (3D) memory, in accordance with a number of embodiments of the present disclosure.

FIG. 11A illustrates a cross-sectional view, taken along cut-line A-A’ in FIG. 9A, showing another view of the semiconductor structure at this particular point in one example semiconductor fabrication process of an embodiment of the present disclosure. The cross-sectional view shown in FIG. 11A is illustrated, right to left in the plane of the drawing sheet, extending in the first direction (D1) 1109. As illustrated in FIG. 11A, a first conductive material 1177 can be conformally deposited fully around the gate dielectric material 1142.

FIG. 11B illustrates a cross-sectional view, taken along cut-line B-B’ in FIG. 9A, showing another view of the semiconductor structure at this particular point in one example semiconductor fabrication process of an embodiment of the present disclosure. The cross-sectional view shown in FIG. 11B is illustrated, right to left in the plane of the drawing sheet, extending in the second direction (D2) 1105.

The semiconductor fabrication process can include depositing the first conductive material 1177 on the gate dielectric material 1142. The first conductive material 1177 may be deposited around the gate dielectric material 1142 such that the first conductive material 1177 may have a top portion above the Si material 1132 and a bottom portion below the Si material 1132 to form gate all around (GAA) gate structures, at the channels of the access device regions. The first conductive material 1177 may be conformally deposited into vertical openings and fill the continuous second horizontal openings. The first conductive material 1177 may be conformally deposited using a chemical vapor deposition (CVD) process, plasma enhanced CVD (PECVD), atomic layer deposition (ALD), or other suitable deposition process.

In some embodiments, the first conductive material 1177 may comprise one or more of a doped semiconductor (e.g., doped silicon, doped germanium, etc., a conductive metal nitride, e.g., titanium nitride, tantalum nitride, etc.), a metal (e.g., tungsten (W), titanium (Ti), tantalum (Ta), ruthenium (Ru), cobalt (Co), molybdenum (Mo), etc.), and/or a metal-semiconductor compound (e.g., tungsten silicide, cobalt silicide, titanium silicide, etc.), and/or some other combination thereof. The first conductive material 1177 entwined with the gate dielectric material may form horizontally oriented access lines at a channel region of the epitaxially grown, single crystalline silicon (Si) material (which also may be referred to a word lines).

FIG. 11C illustrates a cross-sectional view, taken along cut-line C-C’ in FIG. 9A, showing another view of the semiconductor structure at this particular point in one example semiconductor fabrication process of an embodiment of the present disclosure. The cross-sectional view shown in FIG. 11C is illustrated, right to left in the plane of the drawing sheet, extending in the second direction (D2) 1105. As illustrated in FIG. 11C, the first conductive material 1177 has been deposited onto the gate dielectric material 1142 and over the plurality of spaced vertical columns 1188.

FIGS. 12A to 12B illustrate an example method, at one stage of a semiconductor fabrication process, for digit line formation in vertical three-dimensional (3D) memory, in accordance with a number of embodiments of the present disclosure.

FIG. 12A illustrates a cross-sectional view, taken along cut-line B-B’ in FIG. 9A, showing another view of the semiconductor structure at this particular point in one example semiconductor fabrication process of an embodiment of the present disclosure. The cross-sectional view shown in FIG. 12A is illustrated, right to left in the plane of the drawing sheet, extending in the second direction (D2) 1205.

The first conductive material 1277 can be recessed to the channel regions. For example, the first conductive material 1277, formed on the gate dielectric material 1242, may be recessed and etched away from the vertical opening. In some embodiments, the first conductive material 1277 may be etched using an atomic layer etching (ALE) process. In some embodiments, the first conductive material 1277 may be etched using an isotropic etch process. The first conductive material 1277 may be selectively etched leaving the oxide material 1242 covering the Si material 1232 and the first dielectric material 1239 intact. The first conductive material 1277 may be selectively etched in the second direction, in the continuous second horizontal openings, a third distance in a range of twenty (20) to fifty (50) nanometers (nm) back from the vertical opening. The first conductive material 1277 may be selectively etched around the Si material 1232 back into the continuous second horizontal openings extending in the first horizontal direction.

FIG. 12B illustrates a cross-sectional view, taken along cut-line C-C’ in FIG. 9A, showing another view of the semiconductor structure at this particular point in one example semiconductor fabrication process of an embodiment of the present disclosure. The cross-sectional view shown in FIG. 12B is illustrated, right to left in the plane of the drawing sheet, extending in the second direction (D2) 1205. As illustrated in FIG. 12B, the first conductive material 1277 has been selectively etched away from the vertical opening and off of the plurality of spaced vertical columns 1288.

FIGS. 13A to 13B illustrate an example method, at one stage of a semiconductor fabrication process, for digit line formation in vertical three-dimensional (3D) memory, in accordance with a number of embodiments of the present disclosure.

FIG. 13A illustrates a cross-sectional view, taken along cut-line B-B’ in FIG. 9A, showing another view of the semiconductor structure at this particular point in one example semiconductor fabrication process of an embodiment of the present disclosure. The cross-sectional view shown in FIG. 13A is illustrated, right to left in the plane of the drawing sheet, extending in the second direction (D2) 1305.

The semiconductor fabrication process can include depositing an inter-layer dielectric (ILD) fill material 1367 in the vertical opening. For example, the ILD fill material 1369 may be deposited into the vertical openings, filling the continuous second horizontal openings up to the unetched portions of the oxide material 1342, the first dielectric material 1339, and the first conductive material 1377. The ILD fill material 1367 may be conformally deposited using a chemical vapor deposition (CVD) process, plasma enhanced CVD (PECVD), atomic layer deposition (ALD), or other suitable deposition process.

FIG. 13B illustrates a cross-sectional view, taken along cut-line C-C’ in FIG. 9A, showing another view of the semiconductor structure at this particular point in one example semiconductor fabrication process of an embodiment of the present disclosure. The cross-sectional view shown in FIG. 13B is illustrated, right to left in the plane of the drawing sheet, extending in the second direction (D2) 1305. As illustrated in FIG. 13B, the first conductive material 1377 has been deposited onto the gate dielectric material 1342 and over the plurality of spaced vertical columns 1388.

FIGS. 14A to 14B illustrate an example method, at one stage of a semiconductor fabrication process, for digit line formation in vertical three-dimensional (3D) memory, in accordance with a number of embodiments of the present disclosure.

FIG. 14A illustrates a cross-sectional view, taken along cut-line B-B’ in FIG. 9A, showing another view of the semiconductor structure at this particular point in one example semiconductor fabrication process of an embodiment of the present disclosure. The cross-sectional view shown in FIG. 14A is illustrated, right to left in the plane of the drawing sheet, extending in the second direction (D2) 1405.

As illustrated in FIG. 14A, the ILD material 1467 can be removed from the vertical opening and up to a vertical sidewall of the vertical opening. This results in a vertical stack in the vertical opening of alternating ILD material 1467, dielectric material 1439, ILD material 1467, gate dielectric material 1442, Si material 1432, dielectric material 1442, ILD fill material 1467, etc.

FIG. 14B illustrates a cross-sectional view, taken along cut-line C-C’ in FIG. 9A, showing another view of the semiconductor structure at this particular point in one example semiconductor fabrication process of an embodiment of the present disclosure. The cross-sectional view shown in FIG. 14B is illustrated, right to left in the plane of the drawing sheet, extending in the second direction (D2) 1405. As illustrated in FIG. 14B, the ILD fill material 1467 has been removed from the vertical opening and from the plurality of spaced vertical columns 1488.

FIGS. 15A to 15B illustrate an example method, at one stage of a semiconductor fabrication process, for digit line formation in vertical three-dimensional (3D) memory, in accordance with a number of embodiments of the present disclosure.

FIG. 15A illustrates a cross-sectional view, taken along cut-line B-B’ in FIG. 9A, showing another view of the semiconductor structure at this particular point in one example semiconductor fabrication process of an embodiment of the present disclosure. The cross-sectional view shown in FIG. 15A is illustrated, right to left in the plane of the drawing sheet, extending in the second direction (D2) 1505.

In some embodiments, the semiconductor fabrication process can include epitaxially growing Si material between the plurality of spaced vertical columns 1588 to form the plurality of spaced vertical digit lines 1590. Si material can be epitaxially grown at the first source/drain regions 1521 (e.g., at the tips of the exposed Si material 1532) in the vertical openings between the plurality of spaced vertical columns 1588 of high-k dielectric material. Epitaxially growing Si material can be percreated by flowing silane gas at appropriate temperature and pressure under vacuum conditions to seed and nucleate Si on the ends, e.g., tips, of the exposed Si material 1532. The epitaxially grown Si material can be grown to a point at which it merges in the vertical direction (e.g., direction 1511, D3) to form a continuous, vertically oriented digit line 1590.

In some embodiments, the method includes depositing Si material between the plurality of spaced vertical columns 1588. For example, the Si material can be conformally deposited between the plurality of spaced vertical columns 1588 to form the plurality of spaced vertical digit lines 1590.

FIG. 15B illustrates a cross-sectional view, taken along cut-line C-C’ in FIG. 9A, showing another view of the semiconductor structure at this particular point in one example semiconductor fabrication process of an embodiment of the present disclosure. The cross-sectional view shown in FIG. 15B is illustrated, right to left in the plane of the drawing sheet, extending in the second direction (D2) 1505. As illustrated in FIG. 15B, the continuous, vertically oriented digit lines 1590 have been formed.

As illustrated in FIG. 15B, the plurality of spaced vertical columns 1588 can prevent substantial horizontal growth (e.g., in direction D1, shown in the cross-section in FIG. 9A). The plurality of spaced vertical columns 1588 can accordingly prevent merging in the horizontal direction (e.g., direction D1) of the Si material, which can prevent short-circuiting between vertically oriented digit lines in the 3D memory array.

At this point in the semiconductor fabrication process, the continuous, vertically oriented digit lines 1590 are still Si material. For example, the vertically oriented digit lines 1590 may be epitaxially grown or deposited Si material. As such, the semiconductor fabrication process can further include converting the continuous, vertically oriented digit lines 1590 from the Si material to a conductive material having a different characteristic from the Si material.

The Si material of the vertically oriented digit lines 1590 can be converted to conductive material (e.g., tungsten material). For instance, a tungsten hexafluoride (WF6) material can be selectively reacted with the remaining Si material. For example, the tungsten hexafluoride material can be flowed into the third vertical opening to expose the digit lines 1590 to the tungsten hexafluoride material, such that the (e.g., exposed) vertically oriented digit lines 1590 are soaked with the tungsten hexafluoride, causing the tungsten material to grow. This reaction can be expressed chemically as:

WF₆ + 3/2 Si W + 3/2 SiF₄

with the change in enthalpy for the reaction being -1908 KJ/mole. The tungsten hexafluoride may target all iterations of the vertically oriented digit lines 1590 in the stack.

The tungsten hexafluoride material, however, may react only with the Si material. For instance, the tungsten hexafluoride material may not react with dielectric material, source/drain region, or oxide material. Hence, the conversion process may be selective to the Si material of the continuous, vertically oriented digit lines 1590. For instance, the dielectric material, source/drain region, and oxide material may be left intact during the conversion process, and the source/drain region may remain nearly untouched by the conversion process.

As such, the Si material can be converted into a conductive material to function as a vertically oriented digit line. The vertically oriented digit line formation as described above can be utilized in vertical openings having high aspect ratios, such as 5:1 vertical/horizontal aspect ratio specifications, or even higher.

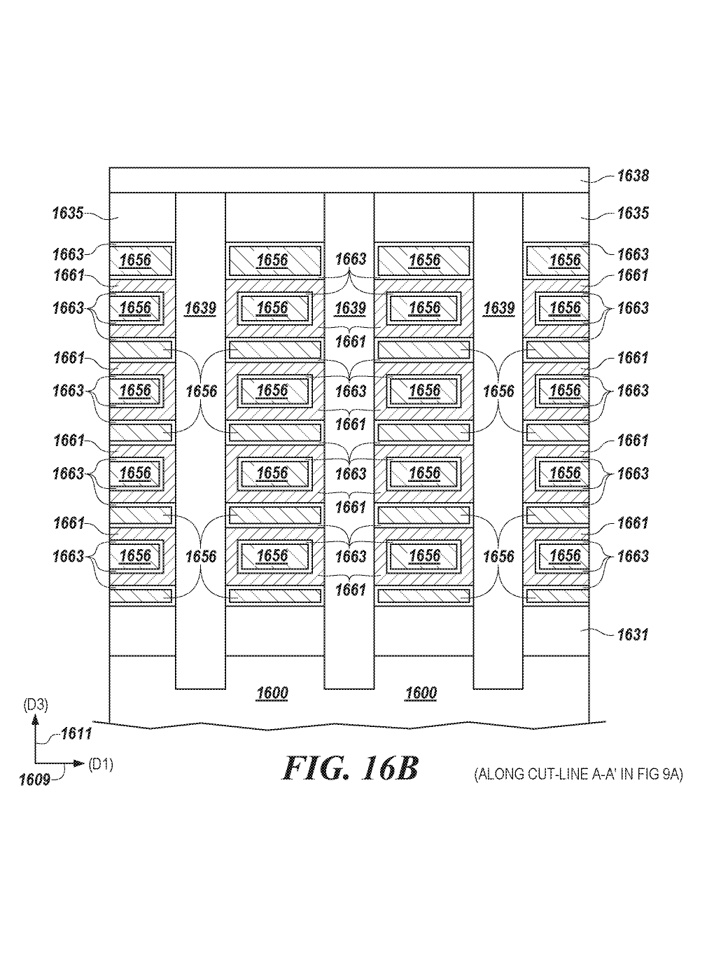

FIGS. 16A-16B illustrate an example method, at one stage of a semiconductor fabrication process, for digit line formation in vertical three-dimensional (3D) memory, in accordance with a number of embodiments of the present disclosure.

FIG. 16A illustrates a cross-sectional view, taken along cut-line B-B’ in FIG. 9A, showing another view of the semiconductor structure at this particular point in one example semiconductor fabrication process of an embodiment of the present disclosure. The cross-sectional view shown in FIG. 16A is illustrated, right to left in the plane of the drawing sheet, extending in the second direction (D2) 1605.

In FIG. 16A, one or more etchant processes can be utilized to form the storage node region 1650. The storage node region 1650 can include storage nodes (e.g., horizontally oriented capacitor cells) having the first electrodes 1661, e.g., bottom electrodes to be connected to source/drain regions of horizontal access devices, and second electrodes 1656, e.g., top electrodes to be connected to a common electrode plane such as a ground plane. The storage nodes are shown formed in a third horizontal opening 1679, extending in second direction (D2) 1605, left and right in the plane of the drawing sheet, a third distance from the vertical opening formed in the vertical stack and along an axis of orientation of the horizontal access devices and horizontal storage nodes of the arrays of vertically stacked memory cells of the three-dimensional (3D) memory. In FIG. 16A, a neighboring, horizontal access line 1677 is illustrated adjacent the second dielectric material 1633, with a portion of the first conductive material 1677 located above the Si material 1632, and a portion of the first conductive material 1677 located below the Si material 1632 extending in a direction inward and outward from the plane and orientation of the drawing sheet.

FIG. 16B is a cross sectional view, taken along cut-line A-A’ in FIG. 9A, showing another view of the semiconductor structure at a particular time in the semiconductor fabrication process. The cross-sectional view shown in FIG. 16B is away from the plurality of separate, horizontal access lines 1677, and shows repeating iterations of alternating layers of second electrodes 1656 separated by horizontally oriented capacitor cells having first electrodes 1661, e.g., bottom cell contact electrodes, cell dielectric material 1663, and top, common node electrodes, on a semiconductor substrate 1600 to form the vertical stack. In the example embodiment of FIG. 16B, the first electrodes 1661, e.g., bottom electrodes to be connected to source/drain regions of horizontal access devices, and second electrodes 1656 are illustrated separated by a cell dielectric material 1663 extending into and out of the plane of the drawing sheet in second direction (D2) and along an axis of orientation of the horizontal access devices and horizontal storage nodes of the arrays of vertically stacked memory cells of the 3D memory. In FIG. 16B, the first dielectric material 1639 is shown separating the space between neighboring horizontally oriented access devices and horizontally oriented storage nodes.

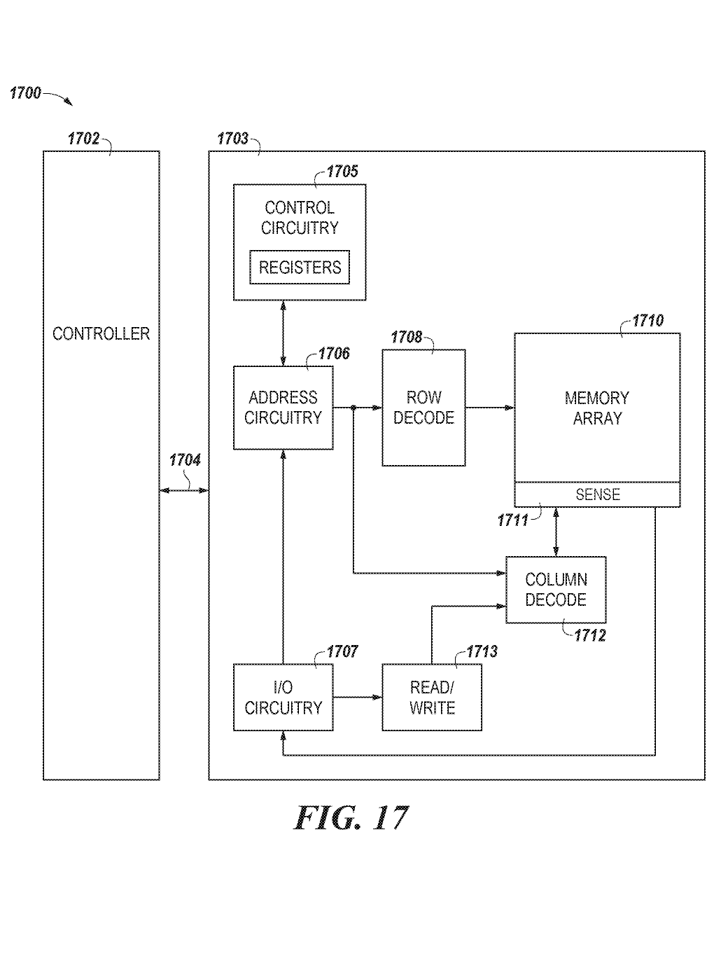

FIG. 17 is a block diagram of an apparatus in the form of a computing system 1700 including a memory device 1703 in accordance with a number of embodiments of the present disclosure. As used herein, a memory device 1703, a memory array 1710, and/or a host 1702, for example, might also be separately considered an “apparatus.” According to embodiments, the memory device 1703 may comprise at least one memory array 1710 with a memory cell formed having a digit line and body contact, according to the embodiments described herein.

In this example, system 1700 includes a host 1702 connected to memory device 1703 via an interface 1704. The computing system 1700 can be a personal laptop computer, a desktop computer, a digital camera, a mobile telephone, a memory card reader, or an Internet-of-Things (IoT) enabled device, among various other types of systems. Host 1702 can include a number of processing resources (e.g., one or more processors, microprocessors, or some other type of controlling circuitry) capable of accessing memory 1703. The system 1700 can include separate integrated circuits, or both the host 1702 and the memory device 1703 can be on the same integrated circuit. For example, the host 1702 may be a system controller of a memory system comprising multiple memory devices 1703, with the system controller 1702 providing access to the respective memory devices 2403 by another processing resource such as a central processing unit (CPU).

In the example shown in FIG. 17, the host 1702 is responsible for executing an operating system (OS) and/or various applications (e.g., processes) that can be loaded thereto (e.g., from memory device 1703 via controller 1702). The OS and/or various applications can be loaded from the memory device 1703 by providing access commands from the host 1702 to the memory device 1703 to access the data comprising the OS and/or the various applications. The host 1702 can also access data utilized by the OS and/or various applications by providing access commands to the memory device 1703 to retrieve said data utilized in the execution of the OS and/or the various applications.

For clarity, the system 1700 has been simplified to focus on features with particular relevance to the present disclosure. The memory array 1710 can be a DRAM array comprising at least one memory cell having a digit line and body contact formed according to the techniques described herein. For example, the memory array 1710 can be an unshielded DL 4F2 array such as a 3D-DRAM memory array. The array 1710 can comprise memory cells arranged in rows connected by word lines (which may be referred to herein as access lines or select lines) and columns connected by digit lines (which may be referred to herein as sense lines or data lines). Although a single array 1710 is shown in FIG. 17, embodiments are not so limited. For instance, memory device 1703 may include a number of arrays 1710 (e.g., a number of banks of DRAM cells).

The memory device 1703 includes address circuitry 1706 to latch address signals provided over an interface 1704. The interface can include, for example, a physical interface employing a suitable protocol (e.g., a data bus, an address bus, and a command bus, or a combined data/address/command bus). Such protocol may be custom or proprietary, or the interface 1704 may employ a standardized protocol, such as Peripheral Component Interconnect Express (PCIe), Gen-Z, CCIX, or the like. Address signals are received and decoded by a row decoder 1708 and a column decoder 1712 to access the memory array 1710. Data can be read from memory array 1710 by sensing voltage and/or current changes on the sense lines using sensing circuitry 1711. The sensing circuitry 1711 can comprise, for example, sense amplifiers that can read and latch a page (e.g., row) of data from the memory array 1710. The I/O circuitry 1707 can be used for bi-directional data communication with the host 1702 over the interface 1704. The read/write circuitry 1713 is used to write data to the memory array 1710 or read data from the memory array 1710. As an example, the circuitry 1713 can comprise various drivers, latch circuitry, etc.

Control circuitry 1705 decodes signals provided by the host 1702. The signals can be commands provided by the host 1702. These signals can include chip enable signals, write enable signals, and address latch signals that are used to control operations performed on the memory array 1710, including data read operations, data write operations, and data erase operations. In various embodiments, the control circuitry 1705 is responsible for executing instructions from the host 1702. The control circuitry 1705 can comprise a state machine, a sequencer, and/or some other type of control circuitry, which may be implemented in the form of hardware, firmware, or software, or any combination of the three. In some examples, the host 1702 can be a controller external to the memory device 1703. For example, the host 1702 can be a memory controller which is connected to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “connected” may include electrically connected, directly connected, and/or directly connected with no intervening elements (e.g., by direct physical contact), indirectly connected and/or connected with intervening elements, or wirelessly connected. The term connected may further include two or more elements that co-operate or interact with each other (e.g., as in a cause and effect relationship). An element connected between two elements can be between the two elements and connected to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” an other element, the particular element can cover the other element, can be over the other element or lateral to the other element and/or can be in direct physical contact the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed:

1. A method for forming arrays of memory cells, comprising:
forming a stack having alternating layers of silicon germanium (SiGe) material and silicon (Si) material from a substrate;
forming access devices in the stack and having respective gates formed at a different level from each other, wherein forming the access devices includes:
forming a first opening through the stack and extending predominantly in a first direction; and
forming a plurality of spaced columns adjacent to first source/drain regions of the access devices;
forming storage nodes in the vertical stack; and
forming, between the plurality of spaced columns, a plurality of spaced vertical digit lines that are electrically connected to the first source/drain regions.

2. The method of claim 1, wherein the method includes forming the plurality of spaced columns prior to forming the storage nodes.

3. The method of claim 1, wherein the method includes depositing a sacrificial dielectric material in the first opening to fill the first opening.

4. The method of claim 3, wherein the method includes:
patterning a mask on a top surface of the stack; and
selectively removing portions of the sacrificial dielectric material in the first opening to form a plurality of spaced vertical openings.

5. The method of claim 4, wherein the method includes depositing a selectively etchable dielectric fill material in the plurality of spaced vertical openings to form the plurality of spaced columns.

6. The method of claim 5, wherein the method includes removing the sacrificial dielectric material from the first opening to define a void in the first opening, the void having the plurality of spaced columns.

7. The method of claim 1, wherein forming the access devices and the storage nodes at each level of the stack comprises:
forming a plurality of second openings, having a first horizontal direction and a second horizontal direction, through the vertical stack, the second openings extending predominantly in the second horizontal direction to form elongated vertical columns with first vertical sidewalls in the stack, separating memory cells on each level;
doping the first source/drain regions of the Si layers at the second opening;
depositing a first dielectric in the plurality of second openings; and
forming a third opening through the stack and extending predominantly in the first horizontal direction to expose second vertical sidewalls in the stack.

8. The method of claim 7, wherein forming the access devices and the storage nodes at each level of the stack further comprises:
selectively etching the silicon germanium (SiGe) layers and reducing a thickness of the Si layers to form a plurality of first horizontal openings a first length (L1) from the third opening;
conformally depositing a second dielectric material on exposed surfaces in the plurality of first horizontal openings; and
forming the plurality of spaced columns adjacent to the first source/drain regions.

9. The method of claim 8, wherein forming the access devices and the storage nodes at each level of the stack further comprises:
recessing the second dielectric material between the plurality of spaced columns to expose the first source/drain regions;
depositing the first dielectric material to fill the plurality of first horizontal openings;
selectively etching the second dielectric material from the plurality of first horizontal openings a second length (L2) from the second opening;
forming a gate dielectric material on exposed surfaces of the reduced thickness of the Si layers;
depositing a first conductive material on the Si layers to form gate all around (GAA) structures at channel regions of the access devices;
recessing the first conductive material to the channel regions; and
capping the first horizontal openings with the second dielectric material.

10. A method for forming arrays of vertically stacked memory cells having horizontally oriented access devices and horizontally oriented storage nodes, comprising:
forming a vertical stack having alternating layers of silicon germanium (SiGe) material and silicon (Si) material from a substrate;
forming the horizontally oriented access devices in the vertical stack each having gates formed horizontally at a different level from each other, channel regions, first source/drain regions, and second source/drain regions separated by the channel regions, wherein forming the horizontally oriented access devices includes:
forming a first vertical opening through the vertical stack and extending predominantly in a first horizontal direction; and
depositing a sacrificial dielectric material in the first vertical opening to fill the first vertical opening;
patterning a mask on a top surface of the vertical stack;
selectively removing portions of the sacrificial dielectric material in the first vertical opening to form a plurality of spaced vertical openings; and
depositing a selectively etchable dielectric fill material in the plurality of spaced vertical openings to form a plurality of spaced vertical columns adjacent to the first source/drain regions;
forming horizontally oriented storage nodes in the vertical stack; and
forming, between the plurality of spaced vertical columns, a plurality of spaced vertical digit lines that are electrically connected to the first source/drain regions.

11. The method of claim 10, wherein the method includes depositing the selectively etchable dielectric fill material to form the plurality of spaced vertical columns such that a second dielectric material separates the plurality of spaced vertical columns from a first conductive material of gate all around (GAA) structures.

12. The method of claim 10, wherein the method includes depositing the selectively etchable dielectric fill material as a high-k dielectric material to form the plurality of spaced vertical columns.

13. The method of claim 10, wherein the method includes epitaxially growing Si material between the plurality of spaced vertical columns to form the plurality of spaced vertical digit lines.

14. The method of claim 10, wherein the method includes depositing, after forming the plurality of spaced vertical digit lines, an oxide material in the first vertical opening to fill the first vertical opening.

15. The method of claim 10, wherein the method includes capping, after forming the plurality of spaced vertical digit lines, the top surface of the stack with oxide to seal the first vertical opening such that an air gap exists in the first vertical opening.

16. The method of claim 10, wherein the method includes depositing Si material between the plurality of spaced vertical columns to form the plurality of spaced vertical digit lines.

17. The method of claim 10, wherein forming the horizontally oriented access devices and horizontally oriented storage nodes at each level of the vertical stack comprises:
forming a plurality of second vertical openings, having a first horizontal direction and a second horizontal direction, through the vertical stack, the second vertical openings extending predominantly in the second horizontal direction to form elongated vertical columns with first vertical sidewalls in the stack, separating memory cells on each level;
doping the first source/drain regions of the Si layers at the second vertical opening;
filling the plurality of second vertical openings with a first dielectric material;
forming a third vertical opening through the vertical stack and extending predominantly in the first horizontal direction to expose second vertical sidewalls in the stack;
selectively etching the silicon germanium (SiGe) layers and reducing a vertical thickness of the Si layers to form a plurality of first horizontal openings a first length (L1) from the third vertical opening;
conformally depositing a second dielectric material on exposed surfaces in the plurality of first horizontal openings;
forming the plurality of spaced vertical columns adjacent to the first source/drain regions;
recessing the second dielectric material between the plurality of spaced vertical columns to expose the first source/drain regions;
depositing the first dielectric material to fill the plurality of first horizontal openings;
selectively etching the second dielectric material from the plurality of first horizontal openings a second length (L2) from the second vertical opening;
forming a gate dielectric material on exposed surfaces of the reduced vertical thickness of the Si layers;
depositing a first conductive material on the Si layers to form gate all around (GAA) structures at the channel regions of the access devices;
recessing the first conductive material to the channel regions;
capping the first horizontal openings with the second dielectric material; and
recessing the second dielectric material to expose the first source/drain regions.

18. A memory device, comprising:
an array of vertically stacked memory cells having horizontally oriented access devices, and horizontally oriented storage nodes, wherein:
the horizontally oriented access devices include channel regions, first source/drain regions, second source/drain regions separated by the channel regions, and gates on a gate dielectric material; and
the horizontally oriented storage nodes are formed horizontally on the second source/drain regions of the horizontally oriented access devices; and
vertical digit lines separated by a plurality of spaced vertical columns comprised of a selectively etchable dielectric fill material, wherein the vertical digit lines are connected to the first source/drain regions of the horizontally oriented access devices.

19. The memory device of claim 18, wherein the array comprises horizontally oriented access lines forming the gates to the horizontally oriented access devices.

20. The memory device of claim 19, wherein the horizontally oriented access lines are gate all around (GAA) structures.
